(19) United States
(12) Patent Application Publication
(10) Pub. No.: US 2019/0121210 A1
(43) Pub. Date: Apr. 25, 2019

(54) LIQUID CRYSTAL DISPLAY DEVICE

(71) Applicant: Mitsubishi Electric Corporation, Tokyo (JP)

(72) Inventors: Tsutomu MATSUURA, Kumamoto (JP); Tetsuya SATAKE, Tokyo (JP); Shingo NAGANO, Kumamoto (JP)

(73) Assignee: Mitsubishi Electric Corporation, Tokyo (JP)

(21) Appl. No.: 16/144,292

(22) Filed: Sep. 27, 2018

(30) Foreign Application Priority Data
Oct. 20, 2017 (JP) 2017-203475

(51) Int. Cl. G02F 1/1362; G02F 1/1337; G02F 1/1343; G02F 1/1335; H01L 27/12

(52) U.S. Cl. CPC G02F 1/136286; G02F 1/133707; G02F 1/134309; G02F 1/133512; G02F 2201/123; H01L 27/124; H01L 27/1288; G02F 2201/121; G02F 1/133514

(57) ABSTRACT

A liquid crystal display device includes pixel structures disposed in a matrix, and includes a display surface flat in a non-curved direction and curved in a curved direction orthogonal to the non-curved direction. The liquid crystal display device includes a liquid crystal layer, a counter substrate, and an array substrate. The counter substrate faces to the liquid crystal layer, includes a black matrix, and is curved along the display surface. The array substrate holds the liquid crystal layer between the array substrate and the counter substrate, and is curved along the display surface and provided with first electrode lines extending in a direction orthogonal to the non-curved direction and second electrode lines intersecting with the first electrode lines. Two or more of the second electrode lines are disposed between pixel structures adjacent to each other in a direction intersecting with the non-curved direction.

### BACKGROUND OF THE INVENTION

### Field of the Invention

The present invention relates to a liquid crystal display device, and particularly relates to a liquid crystal display device including a curved display surface.

### Description of the Background Art

Typically, a transmissive liquid crystal display device (LCD) is formed by laminating a liquid crystal panel and a backlight. The liquid crystal panel includes a pair of planer glass substrates, liquid crystal encapsulated therebetween and having flowability, and polarization plates disposed on outer surfaces of the glass substrate. The liquid crystal display device typically has a plane display surface, but can have a curved display surface by using a thin glass having a thickness of 0.3 mm or smaller or a flexible substrate such as a plastic film. Accordingly, the freedom of designing can be increased, and a function excellent in practical use can be provided. For example, reflection of external light can be effectively reduced by using a particular curved surface shape (see, Japanese Patent Application Laid-Open No. 6-3650).

When a liquid crystal display device is manufactured by using a thin glass substrate, a thick glass substrate is used up to halfway through a manufacturing process to maintain the accuracy of patterning various fine structures formed on the surface of the substrate and achieve easiness in handling such as conveyance. Thereafter, two substrates are bonded and then thinned by, for example, etching or polishing (see, Japanese Patent Application Laid-Open No. 2005-128411).

However, when planer glass substrates are bonded, thinned, and then curved, ununiform display at image display can occur due to the influence of the curvature. Although described later in detail, this is because the curvatures of the two substrates are different from each other substantially by the thickness of each substrate, and thus the relative positions of pixel structures disposed on the substrates are displaced in a curved direction. When this positional displacement exceeds an allowable range, unintended light leakage occurs, causing ununiform display. Such positional displacement occurs when curving is performed after bonding in a flat-plate state, and also occurs in a case of using plastic films in place of the glass substrates.

The above-described positional displacement can be reduced by a disclosed method of bonding the two substrates through a resin wall structure formed in a liquid crystal layer (see, Japanese Patent Application Laid-Open No. 2004-219769). In another disclosed method, among pixel structures, a color filter and a black matrix, which are typically provided to a counter substrate, are provided to an array substrate (see, Japanese Patent Application Laid-Open No. 2007-94102). In another disclosed method, a column spacer is provided on a channel of a thin film transistor (TFT) element by using a light-shielding material (see, Japanese Patent Application Laid-Open No. 2002-23170).

In the above-described method disclosed in Japanese Patent Application Laid-Open No. 2004-219769, the wall structure is bonded to each substrate through light irradiation toward light-curing resin, which has been mixed in liquid crystal. Thus, any uncured component remains as impurity in the liquid crystal. A display defect such as image remaining is likely to occur due to this remaining component. In the method disclosed in Japanese Patent Application Laid-Open No. 2007-94102, formation of a color filter and a black matrix, which is typically performed in the process of manufacturing a counter substrate, is performed in the process of manufacturing an array substrate. Accordingly, a longer time is taken for the process of manufacturing an array substrate. Thus, longer time is taken between start and completion of manufacturing of a liquid crystal display device as compared to formation of a color filter and a black matrix in the process of manufacturing a counter substrate, which can be performed in parallel to the process of manufacturing an array substrate. In the method disclosed in Japanese Patent Application Laid-Open No. 2002-23170, light leakage from any component other than a TFT element is not sufficiently considered. A place at which light leakage occurs due to curvature is not limited to the TFT element, and thus this method cannot sufficiently reduce light leakage.

### SUMMARY

The light leakage can be prevented simply and effectively by sufficiently reducing an opening provided to the black matrix to prevent the influence of the positional displacement on display. Specifically, a larger width dimension (dimension in the curved direction) is provided to part of the black matrix covering the vicinity of each electrode line extending in a direction orthogonal to the curved direction. Accordingly, when there is positional displacement to some extent, it is possible to avoid light leakage attributable to the positional displacement. However, as the opening of the black matrix decreases, the aperture ratio of each pixel decreases, and accordingly, the luminance of the liquid crystal display device decreases. In particular, each pixel in a recent liquid crystal display device has been increasingly downsized to achieve high definition, and accordingly, the area ratio of the black matrix relative to the display surface has been increased. In this case, when the opening of the black matrix is further decreased as described above, the adverse decrease of the aperture ratio is likely to increase.

The present invention is intended to solve a problem as described above by providing a liquid crystal display device capable of reducing ununiform display attributable to positional displacement between a pair of curved substrates, and capable of reducing the accompanying decrease of the aperture ratio.

A liquid crystal display device according to the present invention includes a plurality of pixel structures disposed in a matrix, and includes a display surface flat in a non-curved direction and curved in a curved direction orthogonal to the non-curved direction. The liquid crystal display device includes a liquid crystal layer, a counter substrate, and an array substrate. The counter substrate faces to the liquid crystal layer, includes a black matrix, and is curved along the display surface. The array substrate holds the liquid crystal layer between the array substrate and the counter substrate, and is curved along the display surface and provided with a plurality of first electrode lines extending in a direction orthogonal to the non-curved direction and a plurality of second electrode lines intersecting with the plurality of first electrode lines. Two or more of the plurality of second electrode lines are disposed between pixel structures adjacent to each other in a direction intersecting with the non-curved direction.

According to the present invention, two or more second electrode lines are disposed between pixel structures adjacent to each other in the direction intersecting with the non-curved direction. With this configuration, the number of first electrode lines necessary for controlling each pixel structure is reduced. Thus, the area of part of the black matrix covering the vicinity of each first electrode line can be reduced. This allows use of pixel structures in a pattern different from that of a case in which one second electrode line is disposed between pixel structures adjacent to each other in the direction intersecting with the non-curved direction. Accordingly, increased flexibility can be obtained for selection of the pattern of pixel structures. This flexibility can be exploited to reduce ununiform display attributable to positional displacement between a pair of curved substrates, and to reduce the accompanying decrease of the aperture ratio.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view schematically illustrating the configuration of a liquid crystal display device according to a first preferred embodiment of the present invention;

FIG. 2 is a plan view schematically illustrating the shape of a liquid crystal panel included in the liquid crystal display device in FIG. 1 on a ZX plane;

FIG. 3 is a schematic sectional view taken along line III-III in FIG. 2;

FIG. 4 is a partial plan view schematically illustrating the configuration of a counter substrate included in the liquid crystal display device in FIG. 1;

FIG. 5 is a partial plan view illustrating a situation in which a liquid crystal control region is formed by a slit formation region of a common electrode and a pixel electrode in an array substrate included in the liquid crystal display device in FIG. 1;

FIG. 6 is a partial plan view schematically illustrating the configuration of the array substrate included in the liquid crystal display device in FIG. 1;

FIGS. 7 and 8 are each a partial plan view schematically illustrating the internal configuration of the array substrate included in the liquid crystal display device in FIG. 1;

FIG. 9 is a schematic partial cross-sectional view of the liquid crystal display device in FIG. 1 taken along line IX-IX (FIGS. 4 to 8);

FIG. 10 is a cross-sectional view of a structure obtained by performing curving after the outer peripheries of two substrates are bonded to each other, which is taken along a plane orthogonal to a non-curved direction;

FIG. 11 is a cross-sectional view of a structure obtained by performing curving while the outer peripheries of two substrates is displaced relative to each other, which is taken along the plane orthogonal to the non-curved direction;

FIG. 12 is a cross-sectional view illustrating an exemplary method of bonding the outer peripheries of two substrates to each other by performing curving while the outer peripheries of two substrates are displaced relative to each other;

FIG. 13 is a partial plan view schematically illustrating the configuration of the array substrate according to the first preferred embodiment of the present invention;

FIG. 14 is a partial plan view schematically illustrating the configuration of an array substrate according to a comparative example;

FIG. 15 includes a cross-sectional view of a structure obtained by bonding the array substrate according to the comparative example and a counter substrate including a color filter having an excessively large size to each other, which is taken along the plane orthogonal to the non-curved direction, and partial plan views thereof at the center, the left end, and the right end in plan view of a curved surface;

FIG. 16 includes a cross-sectional view of a structure obtained by bonding the array substrate according to the first preferred embodiment of the present invention and a counter substrate including a color filter having an excessively large size to each other, which is taken along the plane orthogonal to the non-curved direction, and partial plan views thereof at the center, the left end, and the right end in plan view of a curved surface;

FIG. 17 includes a cross-sectional view of a structure obtained by bonding the array substrate according to the comparative example and a counter substrate including a color filter having an appropriate size to each other, which is taken along the plane orthogonal to the non-curved direction, and partial plan views thereof at the center, the left end, and the right end in plan view of a curved surface;

FIG. 18 includes a cross-sectional view of a structure obtained by bonding the array substrate according to the first preferred embodiment of the present invention and a counter substrate including a color filter having an appropriate size to each other, which is taken along the plane orthogonal to the non-curved direction, and partial plan views thereof at the center, the left end, and the right end in plan view of a curved surface;

FIG. 19 is a partial plan view illustrating the relation between an opaque electrode on the array substrate according to the comparative example and a region in which the color filter of the counter substrate is to be disposed;

FIG. 20 is a partial plan view illustrating the relation between an opaque electrode on the array substrate according to the first preferred embodiment of the present invention and a region in which the color filter of the counter substrate is to be disposed;

FIG. 21 is a partial plan view schematically illustrating a first process of a method of manufacturing the array substrate included in the liquid crystal display device according to the first preferred embodiment of the present invention;

FIG. 22 includes partial cross-sectional views taken along lines A-A′, B-B′, and C-C′ in FIG. 21;

FIG. 23 is a partial plan view illustrating a second process of the method of manufacturing the array substrate included in the liquid crystal display device according to the first preferred embodiment of the present invention;

FIG. 24 includes partial cross-sectional views taken along lines A-A′, B-B′, and C-C′ in FIG. 23;

FIG. 25 is a partial plan view illustrating a third process of the method of manufacturing the array substrate included in the liquid crystal display device according to the first preferred embodiment of the present invention;

FIG. 26 includes partial cross-sectional views taken along lines A-A′, B-B′, and C-C′ in FIG. 25;

FIG. 27 is a partial plan view illustrating a fourth process of the method of manufacturing the array substrate included in the liquid crystal display device according to the first preferred embodiment of the present invention;

FIG. 28 includes partial cross-sectional views taken along lines A-A′, B-B′, and C-C′ in FIG. 27;

FIG. 29 is a partial plan view illustrating a fifth process of the method of manufacturing the array substrate included in the liquid crystal display device according to the first preferred embodiment of the present invention;

FIG. 30 includes partial cross-sectional views taken along lines A-A′, B-B′, and C-C′ in FIG. 29;

FIG. 31 is a partial plan view illustrating a sixth process of the method of manufacturing the array substrate included in the liquid crystal display device according to the first preferred embodiment of the present invention;

FIG. 32 includes partial cross-sectional views taken along lines A-A′, B-B′, and C-C′ in FIG. 31;

FIG. 33 is a partial plan view illustrating a seventh process of the method of manufacturing the array substrate included in the liquid crystal display device according to the first preferred embodiment of the present invention;

FIG. 34 includes partial cross-sectional views taken along lines A-A′, B-B′, and C-C′ in FIG. 33;

FIG. 35 is a partial plan view schematically illustrating the configuration of a counter substrate included in a liquid crystal display device according to a second preferred embodiment of the present invention;

FIG. 36 is a partial plan view illustrating a situation in which a liquid crystal control region is formed by a slit formation region of a common electrode and a pixel electrode in an array substrate included in the liquid crystal display device according to the second preferred embodiment of the present invention;

FIG. 37 is a partial plan view schematically illustrating the configuration of the array substrate included in the liquid crystal display device according to the second preferred embodiment of the present invention;

FIGS. 38 and 39 are each a partial plan view schematically illustrating the internal configuration of the array substrate included in the liquid crystal display device according to the second preferred embodiment of the present invention; and

FIG. 40 is a plan view for description of the width of a black matrix necessary for covering, with a sufficient margin, the vicinity of a source line extending in the non-curved direction, and the width of a black matrix necessary for covering, with a sufficient margin, the vicinity of a source line extending at an angle relative to the non-curved direction.

### DESCRIPTION OF THE PREFERRED EMBODIMENTS

Preferred embodiments of the present invention will be described below with reference to the accompanying drawings. Any identical or equivalent parts in the drawings are denoted by an identical reference number, and duplicate description thereof will be omitted.

### First Preferred Embodiment

(Entire Structure)

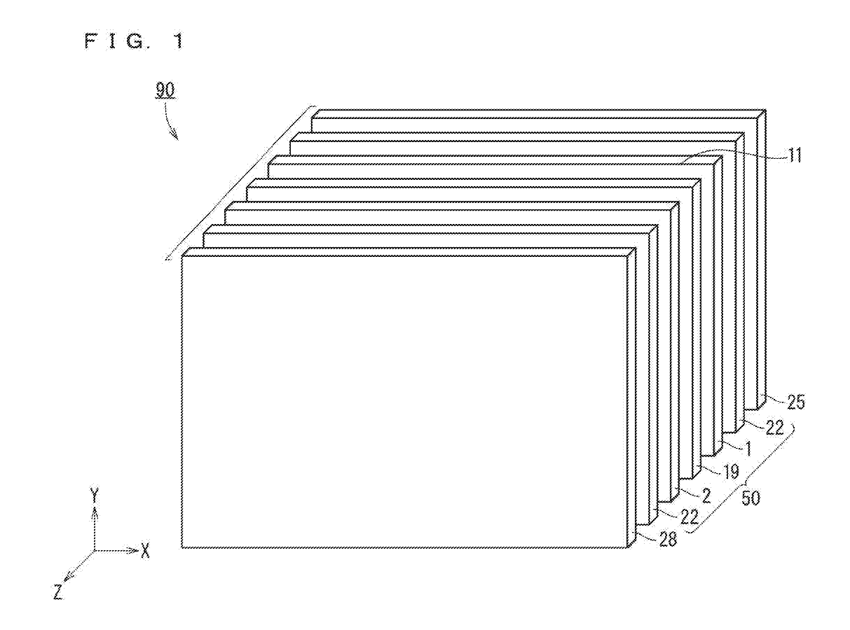

FIG. 1 is an exploded perspective view schematically illustrating the configuration of a liquid crystal display device 90 according to the present preferred embodiment. The liquid crystal display device 90 includes a liquid crystal panel 50, a support plate 28, and a backlight 25. The liquid crystal panel 50 includes an array substrate 1, a liquid crystal layer 19, a counter substrate 2, and a pair of polarization plates 22. The array substrate 1 and the counter substrate 2 each face to the liquid crystal layer 19. In other words, the liquid crystal layer 19 is sandwiched between the array substrate 1 and the counter substrate 2. A spacer (not illustrated) as a column for holding the thickness of the liquid crystal layer 19 constant is provided between the array substrate 1 and the counter substrate 2. The polarization plates 22 are disposed on one surface of this structure and the other surface thereof, respectively. The backlight 25 supplies light to the liquid crystal panel 50, and includes a light source. The light source is, for example, a light-emitting diode. Typically, the backlight also includes a plate for converting a point light source into a surface light source, in other words, a light guiding plate. The liquid crystal panel 50 is stacked on a main surface of the backlight 25 on the light emission side.

The liquid crystal panel 50 includes pixel structures disposed in a matrix. The array substrate 1 includes electrode structures provided for the pixel structures, respectively. Although described later in detail, each electrode structure is connected with a TFT as a switching element. The TFT is turned on when an image signal is input to the corresponding electrode structure. Accordingly, each electrode structure generates an electric field corresponding to the image signal. This electric field controls the polarization direction of liquid crystals of the liquid crystal layer 19. The liquid crystal display device 90 displays a desired image by combining this polarization direction control with selective transmission of polarized light through the pair of polarization plates 22.

Although each component has a planer shape in the exploded view of FIG. 1, the liquid crystal panel 50 is curved as described later. FIG. 1 illustrates an XYZ orthogonal coordinate system. The XYZ orthogonal coordinate system has a direction X, a direction Y, and a direction Z orthogonal to each other.

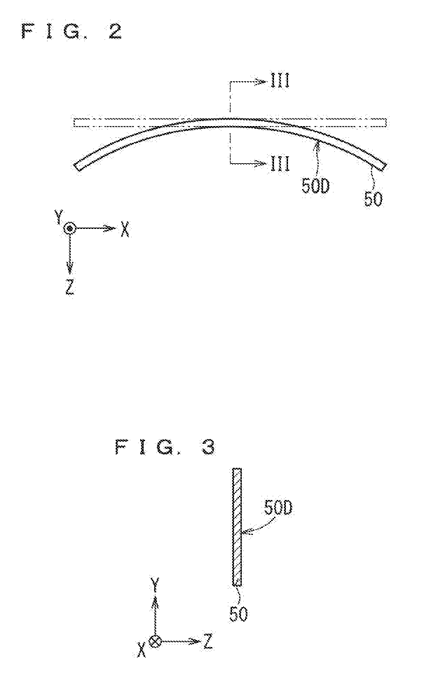

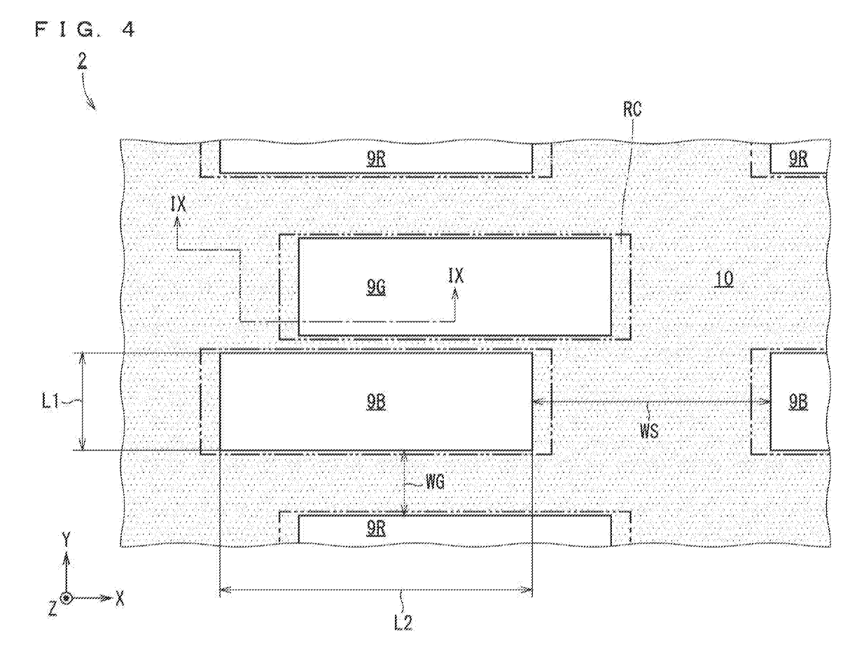

FIG. 2 is a plan view schematically illustrating the shape of the liquid crystal panel 50 on the ZX plane. FIG. 3 is a schematic sectional view taken along line III-III in FIG. 2. The liquid crystal panel 50 includes a display surface 50D. As illustrated in FIG. 2, the display surface 50D has a normal direction in the direction Z at the center thereof, and this normal direction is referred to as a “central normal direction”. As illustrated in FIG. 3, the liquid crystal panel 50 includes the display surface 50D having a flat shape in the direction Y. A direction in which the display surface has a flat shape in this manner is referred to as a “non-curved direction” of the display surface. The non-curved direction of the display surface 50D is along the direction Y. As illustrated in FIG. 2, the display surface 50D does not have a flat shape but is curved in the direction X. This direction in which the curvature exists the direction being orthogonal to the central normal direction (Z direction) and the non-curved direction (direction Y), is referred to as a “curved direction” of the display surface. The curved direction of the display surface 50D is along the direction X. The array substrate 1 and the counter substrate 2 (FIG. 1) are each curved along the display surface 50D. The curvature of the display surface 50D is obtained by curving a flat liquid crystal panel. The curvature of the liquid crystal panel 50 is obtained by bonding the liquid crystal panel 50 to a curved surface provided to the support plate 28. The support plate 28 is made of a translucent material such as glass or acrylic. When the drawings are referred to in the following description, a visual field on a curved surface corresponding to the display surface 50D is also referred to as “plan view of the curved surface”.

(Pixel Structure)

The following describes a specific configuration of each above-described pixel structure.

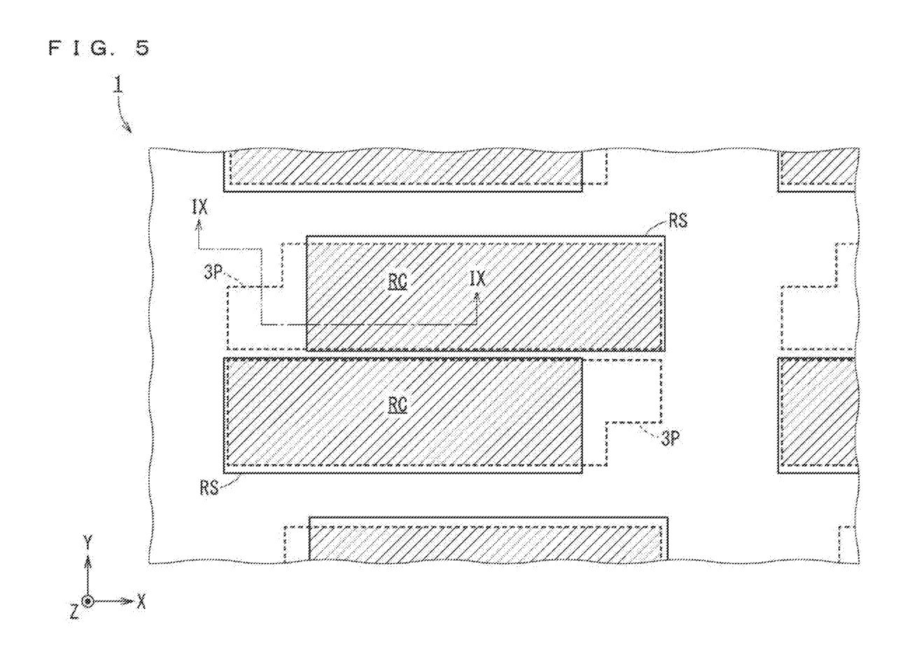

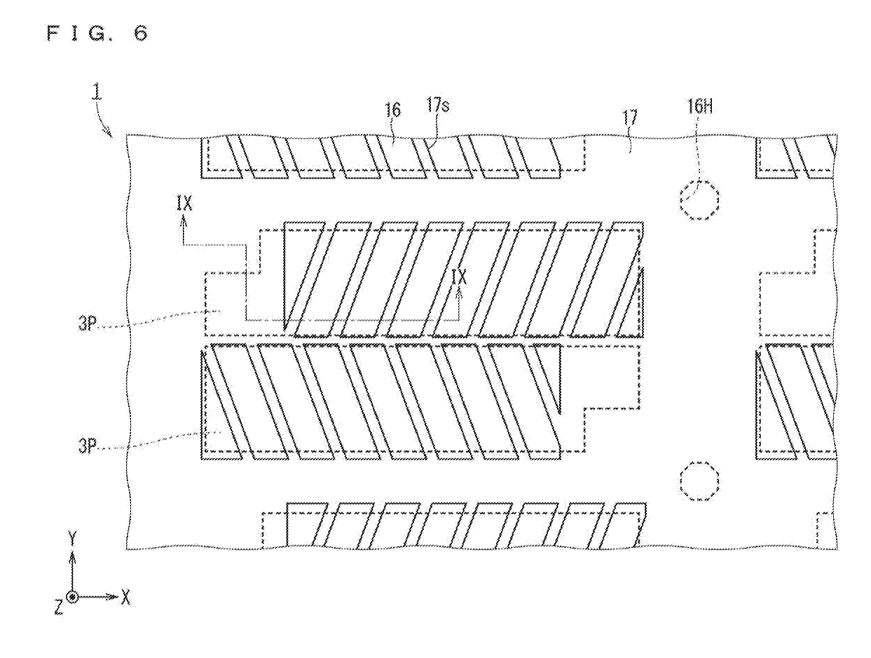

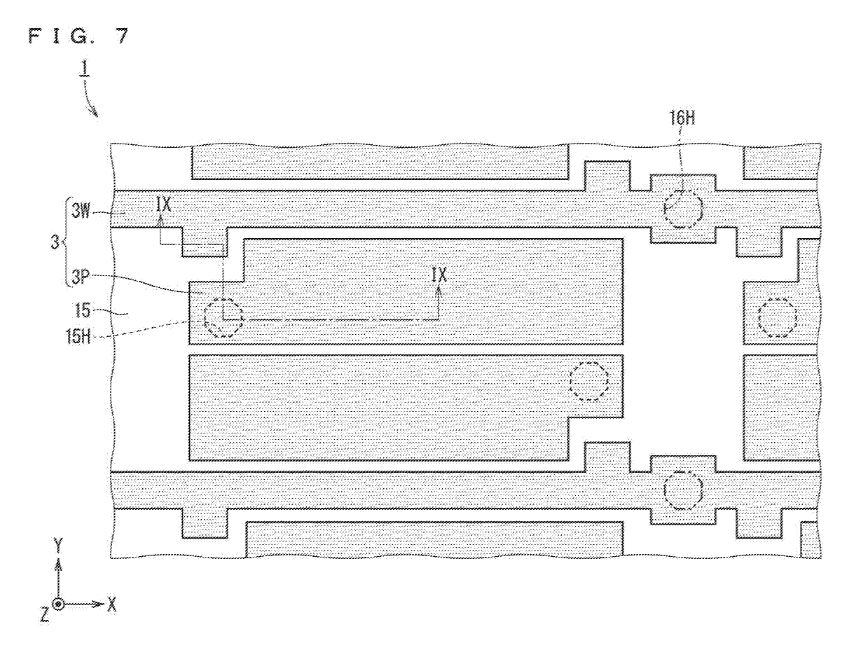

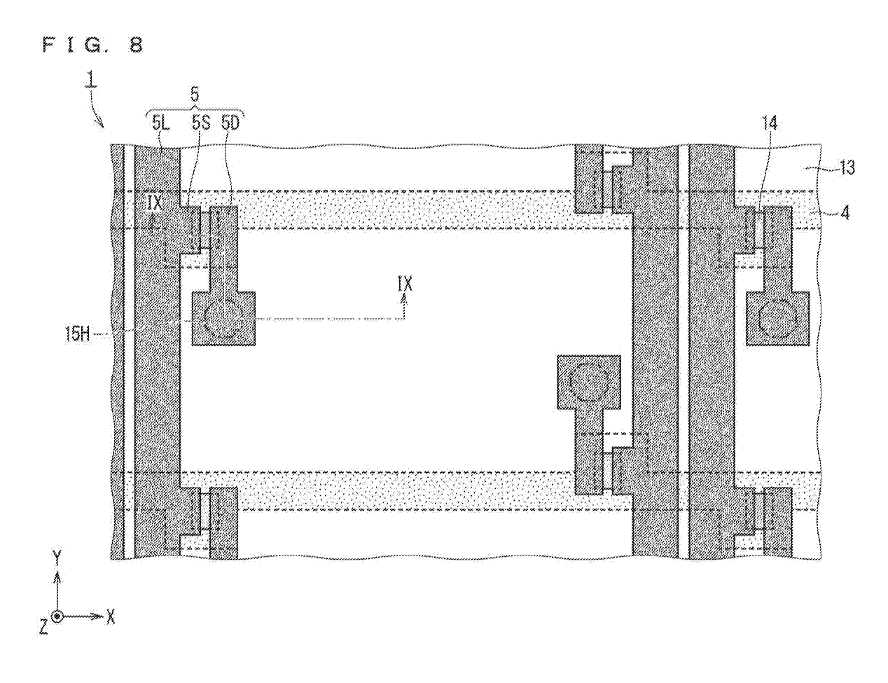

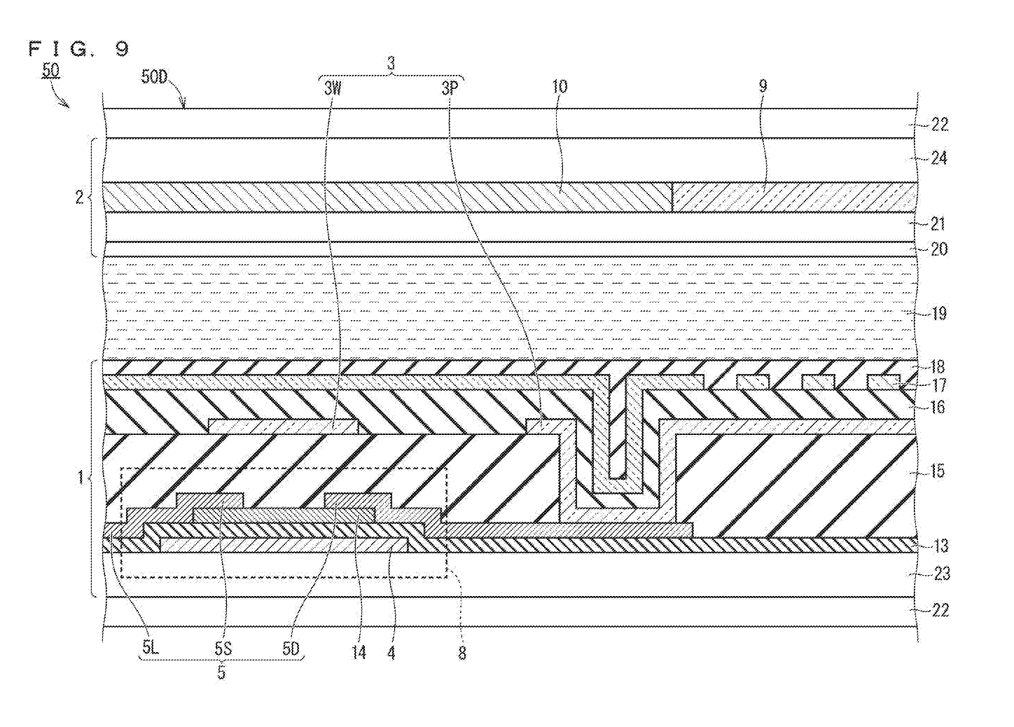

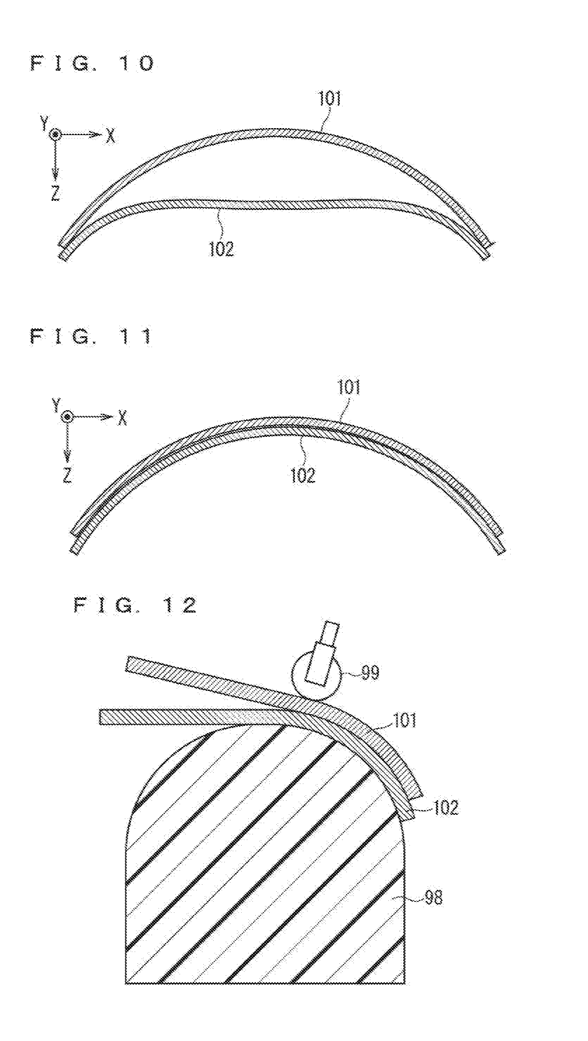

FIG. 4 is a partial plan view schematically illustrating the configuration of the counter substrate 2. FIG. 5 is a partial plan view illustrating a situation in which a liquid crystal control region RC is formed by a slit formation region RS of a common electrode and a pixel electrode 3P in the array substrate 1. FIG. 6 is a partial plan view schematically illustrating the configuration of the array substrate 1. FIGS. 7 and 8 are each a partial plan view schematically illustrating the internal configuration of the array substrate 1. FIG. 9 is a schematic partial cross-sectional view of the liquid crystal panel 50 taken along line IX-IX (FIGS. 5 to 8), schematically illustrating one pixel structure.

As illustrated in FIGS. 4 and 9, the counter substrate 2 includes the polarization plates 22, a glass substrate 24, a black matrix 10, color filters 9R, 9G, and 9B (also collectively referred to as “color filters 9”), an overcoat film 21, and an alignment film 20. For example, the black matrix 10 and the color filters 9 are provided on one surface of the glass substrate 24, and the polarization plates 22 are provided on the other surface of the glass substrate 24. The black matrix 10 has a light-shielding property. The color filters 9R, 9G, and 9B are color filters of red (R), green (G), and blue (B), respectively. Color display in one unit is performed by a set of the color filters 9R, 9G, and 9B. In FIG. 4, the liquid crystal control region RC indicates a region in which liquid crystals can be appropriately controlled by an electric field generated by using the array substrate 1. Each color filter 9 is disposed so as to be included in the liquid crystal control region RC. Arrangement of the color filters 9 corresponds to arrangement of the pixel structures. As illustrated in FIG. 4, each pixel structure, in other words, each color filter 9 has a dimension (first dimension) L1 in the non-curved direction Y, and a dimension (second dimension) L2 in a direction (the lateral direction in FIG. 4) orthogonal to the non-curved direction Y. The dimension L2 is larger than the dimension L1. Accordingly, the pixel structure has a longitudinal direction in the direction (lateral direction in FIG. 4) orthogonal to the non-curved direction Y. In the example illustrated in FIG. 4, each color filter 9 (pixel structure) has a rectangular shape, the short side thereof corresponds to the dimension L1, and the long side thereof corresponds to the dimension L2. The shape of each pixel structure is not limited to a rectangular shape.

As illustrated in FIG. 5, the liquid crystal control region RC is a region in which the pixel electrode 3P and the slit formation region RS of a common electrode 17 (FIG. 6) overlap with each other. The slit formation region RS is a region in which a comb teeth electrode structure is provided by forming slits 17s (FIG. 6) in the common electrode 17. When the comb teeth electrode structure of the common electrode is disposed to face the pixel electrode 3P, a fringe electric field can be generated.

The array substrate 1 (FIG. 9) includes a glass substrate 23 having one surface (in FIG. 9, the lower surface) and the other surface (in FIG. 9, the upper surface). The polarization plate 22 is provided on the one surface of the glass substrate 23. Gate lines (first electrode lines) 4, a gate insulation layer 13, semiconductor layers 14, a metal film 5, a first interlayer insulation layer 15, a conductive film 3, a second interlayer insulation layer 16, the common electrode 17, and an alignment film 18 are sequentially stacked on the other surface of the glass substrate 23.

The gate lines 4 (FIG. 9) are provided on the glass substrate 23. The gate lines 4 are made of an opaque metal such as chromium (Cr), aluminum (Al), or molybdenum (Mo). Each gate line 4 extends in the direction orthogonal to the non-curved direction Y, in other words, the lateral direction in FIG. 8. The gate lines 4 are disposed at intervals in the non-the curved direction. The gate lines 4 are covered by the gate insulation layer 13 (FIG. 9).

The semiconductor layers 14 (FIGS. 8 and 9) are provided on part of the gate lines 4 through the gate insulation layer 13. The part of the gate lines 4 functions as a gate electrode. To obtain a sufficient area for the gate electrode, as illustrated in FIG. 8, each gate line 4 may include protrusions (protrusions downward in FIG. 8) on which the semiconductor layers 14 are disposed. The semiconductor layers 14 are made of, for example, amorphous silicon.

The metal film 5 (FIGS. 8 and 9) includes source lines (second electrode lines) 5L, source electrodes 5S, and drain electrodes 5D. The metal film 5 is made of an opaque metal such as Cr, Al, or Mo. Each source line 5L is insulated from the gate lines 4 by the gate insulation layer 13 as illustrated in FIG. 9, intersects with the gate lines 4 as illustrated in FIG. 8, and is orthogonal to the gate lines 4 in the present preferred embodiment. As illustrated in FIG. 8, each source line 5L is connected with the source electrodes 5S. The drain electrodes 5D are separated from the source lines 5L and the source electrodes 5S. Each semiconductor layer 14 is disposed across the corresponding source electrode 5S and the corresponding drain electrode 5D, which forms a TFT 8 (FIG. 9) for each pixel structure. Two or more of the source lines 5L, are disposed between pixel structures adjacent to each other in a direction intersecting with the non-curved direction Y, in other words, the lateral direction in FIG. 8, and two source lines 5L are disposed therebetween in the present preferred embodiment.

The first interlayer insulation layer 15 (FIG. 9) covers the TFT 8. The first interlayer insulation layer 15 includes a contact hole 15H on the drain electrode 5D.

The conductive film 3 (FIGS. 7 and 9) is provided on the first interlayer insulation layer 15. The conductive film 3 includes the pixel electrodes 3P and common lines 3W separated from each other. The conductive film 3 is made of a transparent conductive material such as indium tin oxide (ITO). Each pixel electrode 3P is connected with the drain electrode 5D through the contact hole 15H. The common lines 3W are disposed substantially along the gate lines 4 as illustrated in, for example, FIGS. 7 and 8.

The second interlayer insulation layer 16 covers the conductive film 3. The second interlayer insulation layer 16 includes a contact hole 16H (FIGS. 6 and 7) on each common line 3W. The common electrode 17 is provided on the second interlayer insulation layer 16. The common electrode 17 is connected with the common line 3W through the contact hole 16H. With this configuration, the common electrode 17 is provided with common potential. The common electrode 17 is covered by the alignment film 18.

(Modifications)

The conductive film 3 is made of a transparent material as described above because the translucent pixel electrodes 3P need to be formed in a transmissive LCD configured to perform display by selectively transmitting light from the backlight 25 (FIG. 1). In a modification for a reflective LCD configured to perform display by selectively reflecting external light, the conductive film is made of a metallic material, such as Al or silver (Ag), which reflects light. In a semi-transmissive LCD configured to perform display by both reflection and transmission, pixel electrodes having both light reflectivity and translucency may be formed.

Source lines may be provided in place of gate lines as the first electrode lines extending in the direction orthogonal to the non-curved direction Y. In this case, the gate lines are provided intersecting with the source lines.

The glass substrate may be replaced with a transparent insulation substrate made of a material other than glass, and for example, a plastic film may be used.

(Function and Operation of Each Structure)

The following describes function and operation of each structure disposed in each pixel structure.

Pixels arranged at an identical line in the longitudinal direction are selected by applying a pulsed selection voltage to the corresponding gate line 4 (FIG. 8). In a selection duration in which the selection voltage is applied, an image signal voltage is applied to the source lines 5L (FIG. 8). The TFT 8 (FIG. 9) is turned on in the selection duration, and thus the image signal voltage is applied to the pixel electrodes 3P through the source lines 5L. In this manner, the image signal voltage is applied at once to the pixel electrodes 3P (FIG. 7) at the identical line.

Subsequently, the selection voltage is applied to the adjacent gate line 4, and the above-described operation is repeated. Through the repetition, image signal voltages are applied to all pixel electrodes 3P in a display region. At a pixel in a non-selection duration in which no selection voltage is applied, the TFT 8 is turned off, and thus the potential of the pixel electrode 3P is maintained.

A predetermined voltage is applied to the common electrode 17 disposed on the liquid crystal layer 19 (FIG. 9) side of the array substrate 1, and a fringe electric field is generated due to the voltage between the common electrode 17 and each pixel electrode 3P. Accordingly, the orientation state of liquid crystal molecules in the liquid crystal layer 19 under influence of the fringe electric field changes. The birefringent property of the liquid crystal layer 19 is adjusted depending on the value of the voltage between the pixel electrode 3P and the common electrode 17. Transmissivity is controlled by this adjustment and a combination of the pair of polarization plates 22 provided on the outer surfaces of the array substrate 1 and the counter substrate 2.

Transmitted light at each pixel is colored in any color of R, G, and B through the corresponding color filter 9 disposed on the counter substrate 2 (FIG. 9) side. The transparent overcoat film 21 is disposed on the color fillers 9, which flattens the surface (in FIG. 9, the lower surface) of the counter substrate 2 on the liquid crystal layer 19 side, and shields diffusion of impurities from the color filters 9 to the liquid crystal layer 19.

(Light Leakage Mechanism and Aperture Ratio)

In the array substrate 1 (FIG. 8), the pixels are disposed in regions surrounded by the source lines 5L and the gate lines 4 each made of an opaque metal. The display regions of the pixels are regions in which the color filters 9 are provided in the counter substrate 2 (FIG. 4) in the surrounded regions in plan view.

A width WS of part of the black matrix 10 (FIG. 4) covering the vicinity of each source line 5L (FIG. 8) is larger than the entire width of the source lines 5L (in the present preferred embodiment, two source lines 5L) disposed collectively for the pixels adjacent to each other. A width WG of part of the black matrix 10 (FIG. 4) covering the vicinity of each gate line 4 (FIG. 8) is larger than the width of the one gate line 4 disposed between the pixels adjacent to each other. The black matrix 10 has a pattern determined to prevent light leakage through transparent regions in the vicinities of the source lines 51, and the gate lines 4.

The liquid crystal panel 50 before being curved includes a display surface parallel to the XY plane, and the gate lines 4 having an extending direction along the direction X. When the liquid crystal panel 50 is curved, positional displacement occurs between the array substrate 1 and the counter substrate 2 as described later in detail. In this case, the gate lines 4 extending in the curved direction X cause no positional displacement in the direction Y orthogonal to the extending direction thereof as long as there is no displacement in the direction Y between the array substrate 1 and the counter substrate 2. However, the source lines 5L extending in a direction intersecting with the curved direction X cause positional displacement in a direction (in the present preferred embodiment, the direction X) orthogonal to the extending direction thereof due to the curvature. Thus, when the width WS has an insufficient margin, transparent regions in the vicinities of the source lines 5L are not sufficiently covered by the black matrix 10 due to the curvature. As a result, light leakage occurs. This light leakage causes ununiform display of the liquid crystal display device 90. To avoid this, the margin of the width WS needs to be sufficiently provided for the positional displacement of the source lines 5L attributable to the curvature. Meanwhile, the aperture ratio of the liquid crystal panel 50 decreases as the width WS of the black matrix 10 increases.

According to the present preferred embodiment, the source lines 5L (specifically, two source lines 5L) are collectively disposed between the pixels adjacent to each other. Thus, the width WS needs to be increased as compared to a configuration in which only one source line is disposed between adjacent pixels, which leads to decrease of the aperture ratio. However, the number of gate lines 4 necessary for controlling each pixel is reduced when the number of the source lines 5L is increased. Accordingly, the number of parts of the black matrix 10 that have the width WG is reduced. This can be exploited to increase the aperture ratio. The aperture ratio can be effectively increased particularly when the longitudinal direction of each pixel structure is orthogonal to the non-curved direction Y.

In this manner, the occurrence of ununiform display (light leakage) attributable to positional displacement between the array substrate 1 and the counter substrate 2 can be reduced, and the accompanying decrease of the aperture ratio can be reduced.

(Pixel Structure at Curvature)

The pixel structure of the liquid crystal panel 50 at curvature will be described below.

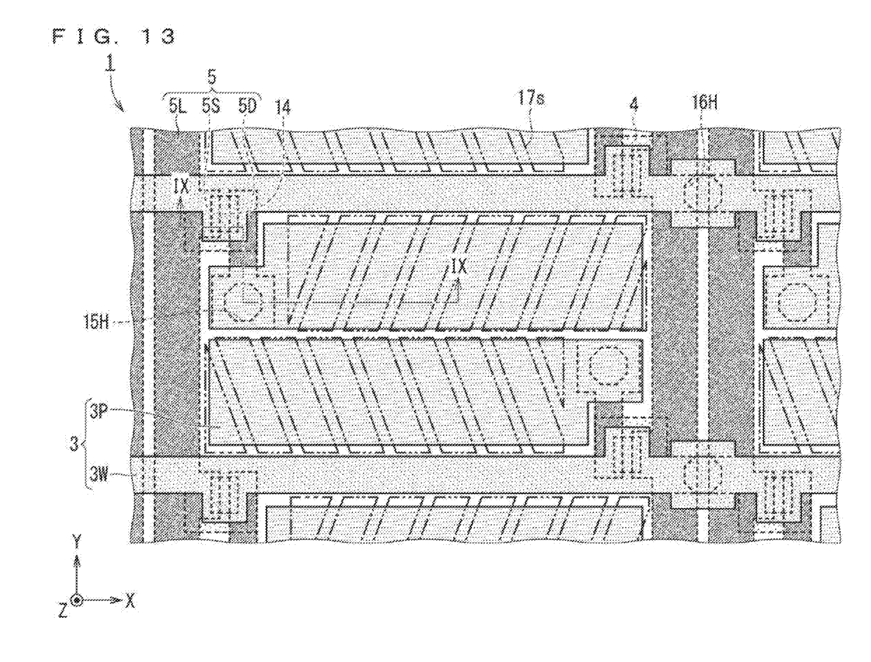

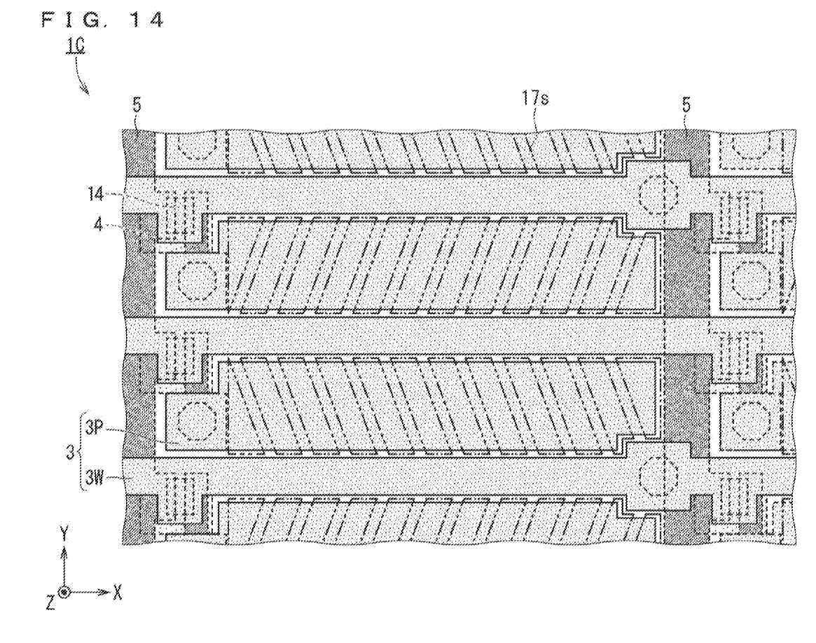

The following first describes a typical phenomenon that occurs at curvature. FIG. 10 is a cross-sectional view of a structure obtained by performing curving after the outer peripheries of a substrate 101 and a substrate 102 are bonded to each other, which is taken along a plane orthogonal to the non-curved direction Y. Since the substrates 101 and 102 are bonded to each other at the outer peripheries thereof, no gap is formed in regions in the vicinities of the outer peripheries. However, in the other region, a gap is formed between the substrates 101 and 102 in accordance with a curvature difference between the substrates 101 and 102 attributable to the thicknesses of the substrates 101 and 102. FIG. 11 is a cross-sectional view of a structure obtained by performing curving while displacing the outer peripheries of the substrates 101 and 102 relative to each other, which is taken along the plane orthogonal to the non-curved direction Y. In this case, a gap as described above can be avoided. Thus, curving needs to be performed while displacing the outer peripheries of the substrates 101 and 102 relative to each other to perform bonding while avoiding unnecessary gap generation. FIG. 12 is a cross-sectional view illustrating an exemplary method of bonding the two substrates to each other by performing curving while displacing the outer peripheries of the substrates. In this method, a support case 98 having a curved surface is used. The substrates 101 and 102 are placed with overlapping each other on this curved surface. Then, the substrates 101 and 102 are bonded to each other while being pressed onto the curved surface by a roller 99. The method illustrated in FIG. 12 is merely an exemplary method of bonding two substrates to each other by performing curving while displacing the outer peripheries of the substrates, and any other method may be employed.

Such displacement between outer peripheries is generated also when an array substrate and a counter substrate are bonded to each other. The following discusses the influence of this displacement. FIGS. 13 and 14 are partial plan views schematically illustrating the configuration of the array substrate 1 according to the present preferred embodiment and the configuration of an array substrate 1C according to a comparative example, respectively. In the array substrate 1C (FIG. 14), only one source line 5L is provided between pixels adjacent to each other in the direction X, and a gate line (hidden behind the common line 3W in FIG. 14) is always provided between pixels adjacent to each other in the direction Y.

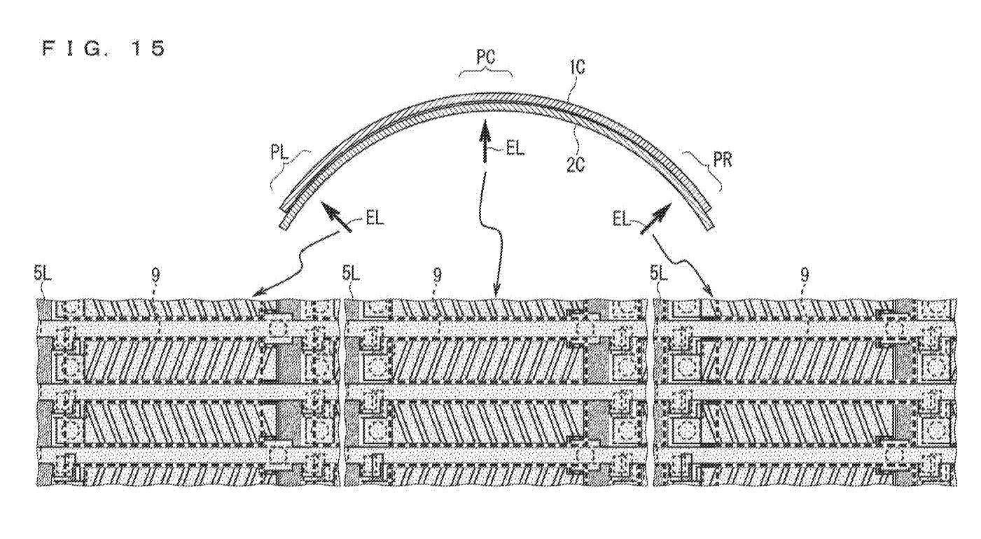

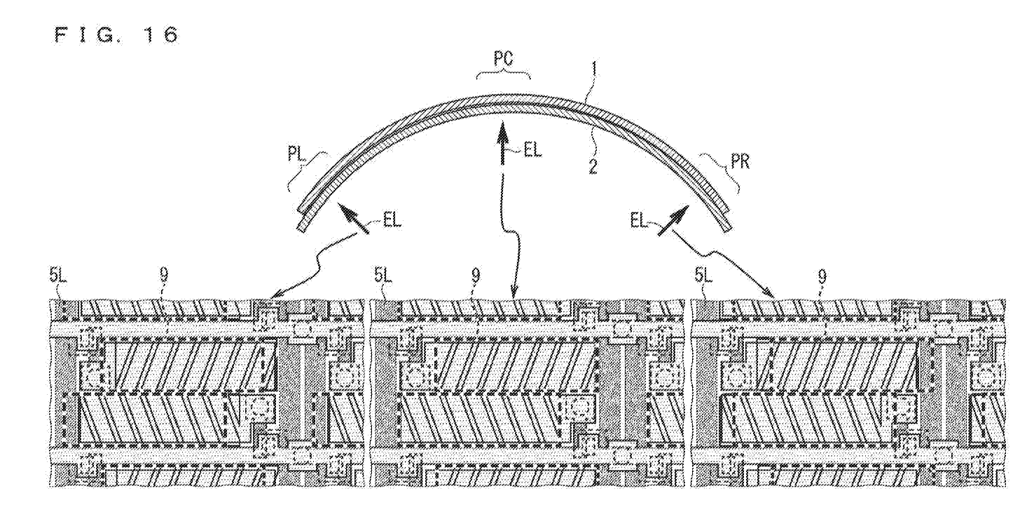

FIG. 15 includes a cross-sectional view, which is taken along the plane orthogonal to the non-curved direction Y, of a structure obtained by bonding to each other the array substrate 1C (FIG. 14) according to the comparative example and a counter substrate 2C including a color filter having an excessively large size, and partial plan views thereof in regions PC, PL, and PR in plan view EL of the curved surface. FIG. 16 includes a cross-sectional view, which is taken along the plane orthogonal to the non-curved direction Y. of a structure obtained by bonding to each other the array substrate 1 according to the present preferred embodiment (FIG. 13) and the counter substrate 2 including a color filter having an excessively large size, and partial plan views thereof in the regions PC, PL, and PR in the plan view EL of the curved surface. The region PC is positioned at the center of the curved surface, and the regions PL and PR are positioned in the vicinities of the left and right ends, respectively, of the curved surface. A region surrounded by a bold dashed line indicates unpreferable exemplary disposition of each color filter 9. Positional displacement still occurs in the regions PL and PR in the vicinities of the ends when bonding is performed between the array substrate and the counter substrate so that no positional displacement occurs therebetween in the region PC at the center of the curved surface. In the region PL in the vicinity of the left end of the curved surface, the color filters 9 are displaced leftward relative to the array substrate. In the region PR in the vicinity of the right end of the curved surface, the color filters 9 are displaced rightward relative to the array substrate. Light from the backlight 25 (FIG. 1) leaks through part of regions not covered by the black matrix due to these displacement, in which opaque members such as the source lines 5L are not disposed. To solve this problem, the areas of the color filters 9 need to be reduced, in other words, the area of the black matrix needs to be increased with taken into account positional displacement between the substrates along with curvature.

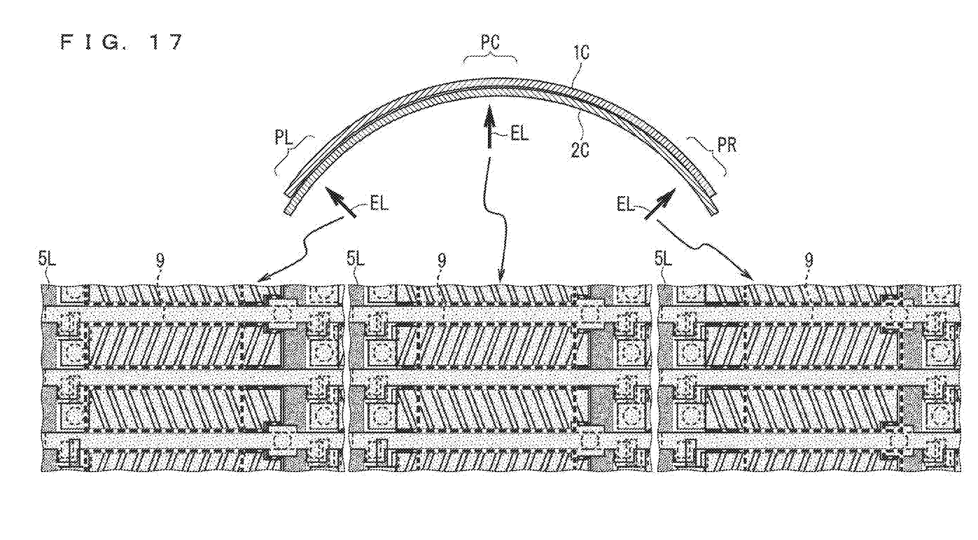

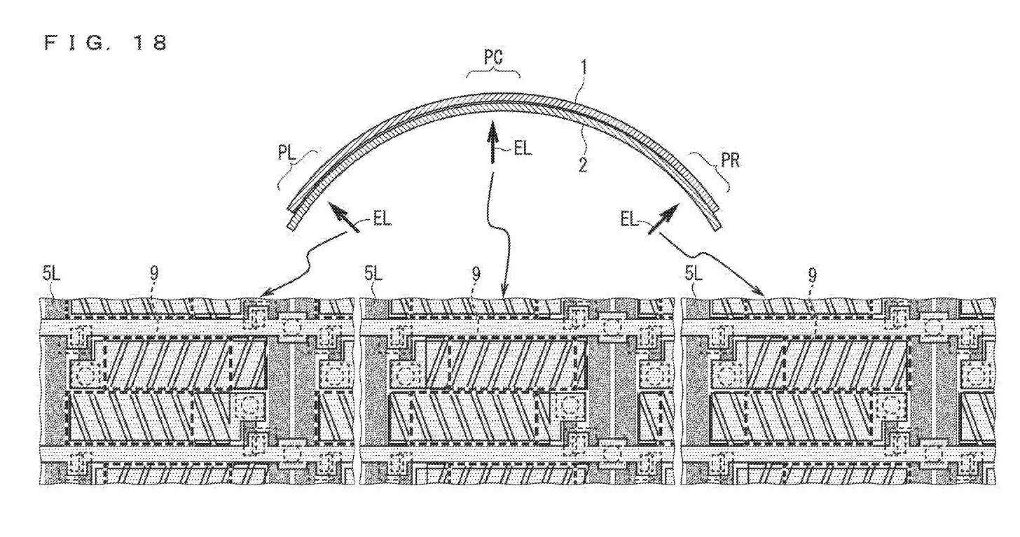

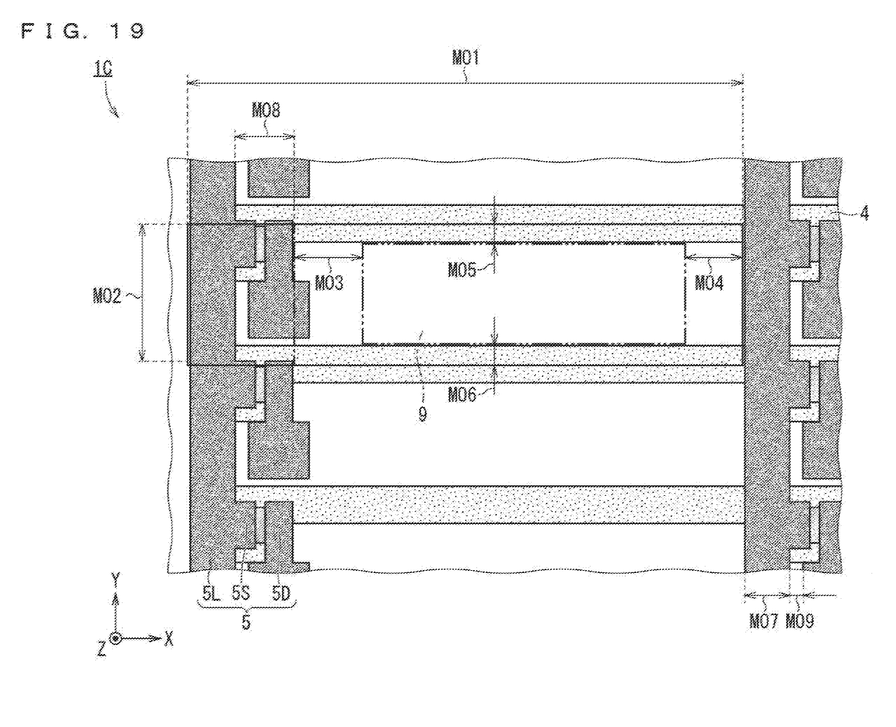

FIG. 17 includes a cross-sectional view, which is taken along the plane orthogonal to the non-curved direction Y, of a structure obtained by bonding to each other the array substrate 1C (FIG. 14) according to the comparative example and the counter substrate 2C including a color filter having an appropriate size, and partial plan views thereof in the regions PC, PL, and PR in the plan view EL of the curved surface. FIG. 18 includes a cross-sectional view, which is taken along the plane orthogonal to the non-curved direction Y, of a structure obtained by bonding to each other the array substrate 1 (FIG. 13) according to the present preferred embodiment and the counter substrate 2 including a color filter having an appropriate size, and partial plan views thereof in the regions PC, PL, and PR in the plan view EL of the curved surface. In a configuration illustrated in these drawings, the color filters 9 having smaller areas are provided with the above-described positional displacement taken into account. With this configuration, the leakage of light from the backlight 25 (FIG. 1) is reduced, but the aperture ratio decreases to some extent. The degree of this decrease is reduced in the present preferred embodiment as compared to the comparative example. The effect of reducing decrease of the aperture ratio will be described below.

(Aperture Ratio in Sub Pixel Unit)

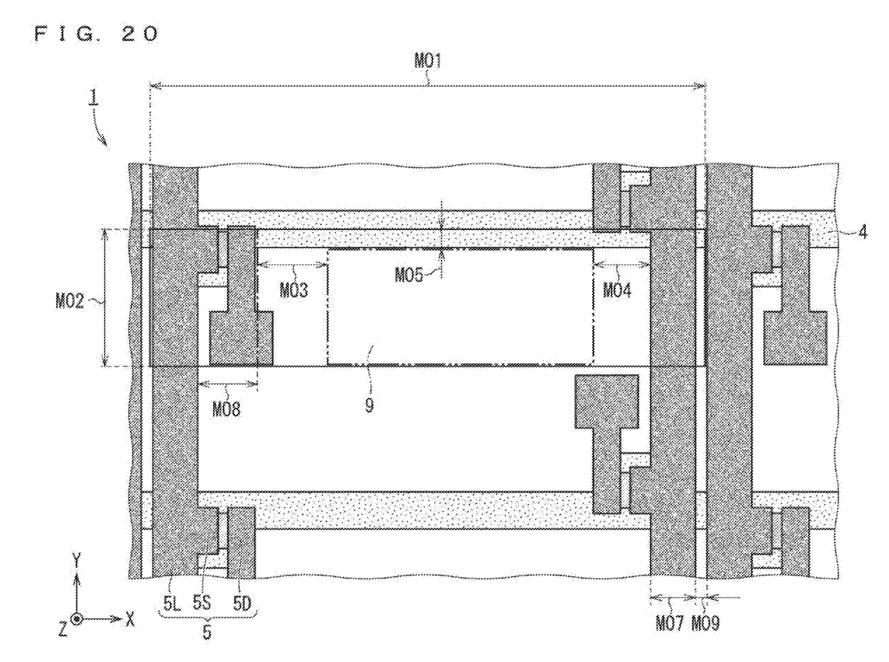

FIG. 19 is a partial plan view illustrating the relation between an opaque electrode on the array substrate 1C according to the comparative example and a region of the counter substrate in which each color filter 9 is to be disposed. FIG. 20 is a partial plan view illustrating the relation between an opaque electrode on the array substrate 1 according to the present preferred embodiment and a region of the counter substrate in which each color filter 9 is to be disposed. In these drawings, a sub pixel lateral length M01 and a sub pixel longitudinal length M02 correspond to the periods of the pixel structures in the lateral direction and the longitudinal direction, respectively. A region included in the sub pixel lateral length M01 and the sub pixel longitudinal length M02 is referred to as a sub pixel unit, and the product thereof is referred to as a sub pixel unit area. Gate electrode widths M05 and M06 each correspond to the width of each gate line 4 included in the sub pixel unit, the sum of the gate electrode widths M05 and M06 corresponds to the width of the gate line 4 in the array substrate 1C (FIG. 19), and the gate electrode width M05 corresponds to half of the width of the gate lines 4 in the array substrate 1 (FIG. 20). This difference is due to reduction of the gate lines 4 at every other line in the array substrate 1 as compared to the array substrate 1C. A source electrode wire width M07 corresponds to the width of each source line 5L. The number of source lines 5L in the sub pixel unit is one for the array substrate 1C, and two for the array substrate 1. A TFT width M08 is the dimension of the TFT 8 (refer to FIG. 9) in the lateral direction. An inter-source-line width M09 is the dimension between two source lines 5L collectively disposed between pixels adjacent to each other in the array substrate 1. A positional displacement margin M03 is a margin for disposing each color filter 9 at a place sufficiently separated from the TFT 8. A positional displacement margin M04 is a margin for disposing each color filter 9 at a place sufficiently separated from the source lines 5L. Designing examples of these dimensions are listed in a table below.

TABLE 1

| | Comparative | | | |
|---|---|---|---|---|
| Item | Example | | Example | |
| Sub pixel lateral length M01 | 150 | μm | 150 | μm |
| Sub pixel longitudinal length M02 | 50 | μm | 50 | μm |
| Positional displacement margin M03 | 5 | μm | 5 | μm |
| Positional displacement margin M04 | 5 | μm | 5 | μm |
| Gate electrode width M05 | 5 | μm | 5 | μm |
| Gate electrode width M06 | 5 | μm | 0 | μm |
| Source electrode wire width M07 | 5 | μm | 5 | μm |
| TFT width M08 | 20 | μm | 20 | μm |
| Inter-source-line width M09 | 0 | μm | 3 | μm |
| Color filter 9: Longitudinal | 40 | μm | 45 | μm |
| Color filter 9: Lateral | 115 | μm | 107 | μm |
| Color filter 9: Area | 4600 | μm² | 4815 | μm² |
| Sub pixel unit area | 7500 | μm² | 7500 | μm² |

| | | |
|---|---|---|
| Aperture ratio | 61.3% | 64.2% |

According to the designing examples, in the comparative example (array substrate 1C), each color filter 9 has longitudinal and lateral dimensions of 40 μm and 115 μm, and thus has an area of 4600 μm². As a result, the aperture ratio is 61.3%. However, in the example (array substrate 1), each color filter 9 has longitudinal and lateral dimensions of 45 μm and 107 μm, and thus has an area of 4815 μm². As a result, the aperture ratio is 64.2%. Accordingly, the aperture ratio according to the example is higher than that of the comparative example. Specifically, the aperture ratio is improved by 3% approximately.

According to the example, each color filter 9 has a reduced lateral dimension and an increased longitudinal dimension as compared to the comparative example. This is because the number of source lines 5L is doubled, and the gate lines 4 are reduced at every other line. This contributes to the improvement of the aperture ratio.

When the pixel structures has a first pixel number in the non-curved direction Y and a second pixel number in the direction orthogonal to the non-curved direction Y, the number of source lines 5L is larger than the second pixel number, and the number of gate lines 4 is smaller than the first pixel number, according to the present preferred embodiment as understood from FIG. 20.

(Pixel Numbers)

The pixel numbers of the liquid crystal panel 50 may be the pixel numbers 1920×1080, which is called Full High Definition (FHD). Recently, a FHD liquid crystal display device has been typical for a commercially available device such as a television or a smartphone, but is still of an extremely high definition class for middle-sized to small-sized on-board and industrial devices, for which high reliability is required as compared to the commercially available device. A TFT provided to an array substrate for FHD is required to have, in particular, capability of charging each of a liquid crystal capacitor and an auxiliary capacitor to a predetermined potential in a selection time. The TFT selection time depends on the number of gate lines. When the number of gate lines is 1080 and the drive frame rate is 60 Hz, the charging time of each pixel is 15 μsec approximately. Meanwhile, the mobility of amorphous silicon used in the TFT is 0.1 to 1.0 cm²·V⁻¹·s⁻¹ approximately, and thus a necessary charging time is 10 μsec approximately although the charging time depends on the channel width and channel length of the TFT and the unit capacitance of a gate insulation film.

With taken into account existence of sub pixels of three kinds of R, G, and B, gate lines having the number three times larger than the pixel number of 1920 are needed, and accordingly, the number of gate lines 4 in the comparative example (refer to FIG. 19) is 3240. Thus, in the comparative example, the charging time of each pixel is 5 ρsec approximately, which is highly likely to result in insufficient charging when amorphous silicon having a relatively low mobility as a semiconductor is used. On the contrary, according to the present preferred embodiment (refer to FIG. 20), the number of gate lines 4 is reduced to half, and accordingly, the number of gate lines 4 is 1620. Thus, the charging time of each pixel is 10 ρsec approximately, which is two times larger than the charging time according to the comparative example. This allows sufficient charging when amorphous silicon is used as a semiconductor. In other words, the number of gate lines 4 is not limited to 1620, but any number equal to or smaller than 1620 is enough to avoid insufficient charging. Thus, amorphous silicon can be used as a semiconductor to reduce manufacturing cost while avoiding decrease of display quality due to insufficient charging.

(Method of Manufacturing Array Substrate 1)

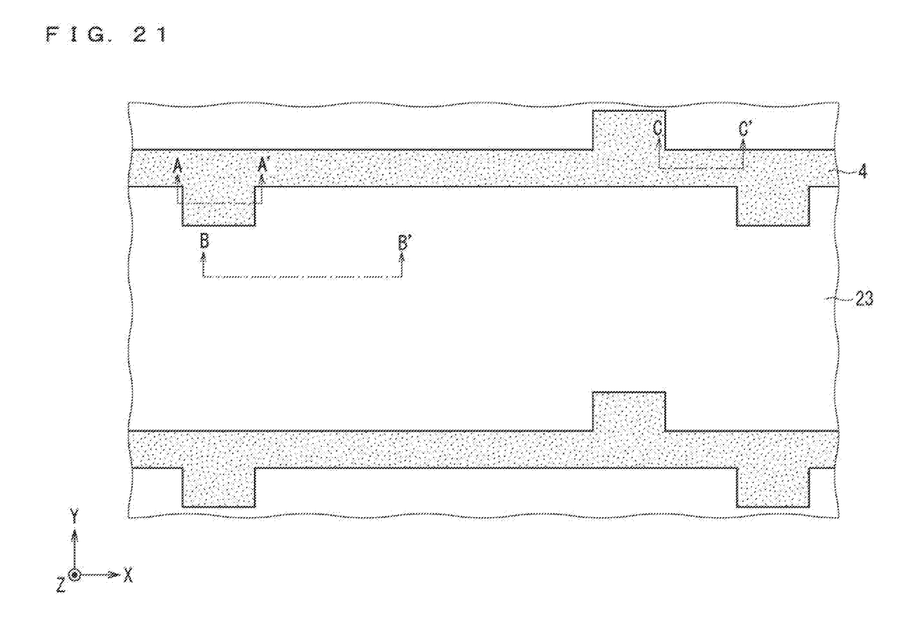

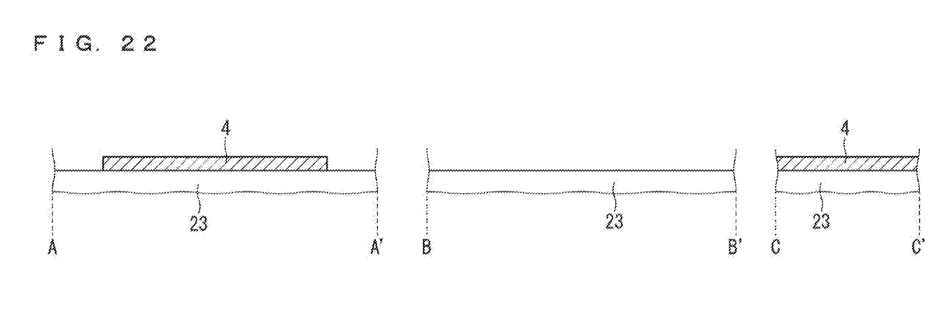

A method of manufacturing the array substrate 1 according to the present preferred embodiment will be described below with a specific example with reference to FIGS. 21 to 34. Partial plan views in FIGS. 21, 23, 25, 27, 29, 31, and 33 correspond to partial cross-sectional views in FIGS. 22, 24, 26, 28, 30, 32, and 34, respectively, where the drawings are illustrated in the order of processes. In the drawings, line A-A′ indicates the position of a section near the TFT 8 (FIG. 9), line B-B′ indicates the position of a section near the contact hole 15H (FIG. 8), and line C-C′ indicates the position of a section near the contact hole 16H (FIG. 7).

As illustrated in FIGS. 21 and 22, first, the glass substrate 23 is cleaned by using cleaning liquid or pure water. Subsequently, a conductive film is deposited and patterned on the glass substrate 23. Through this process, the gate lines 4 are formed on the glass substrate 23. The conductive film may be made of, for example, a metal such as Al, Cr, Cu, or Mo, or an alloy obtained by adding a small amount of another element to these metals. Alternatively, the conductive film may be a laminated film of two or more layers obtained by combining these materials. When these metals and alloys are used, a low resistance film having a specific resistance value equal to or smaller than 50 μΩcm (conductivity equal to or larger than 2×10⁴ S/cm) can be obtained.

In the example, a Mo film having a thickness of 200 nm was deposited on an alkali-free glass substrate having a thickness of 0.5 mm by a sputtering method using Ar gas. Thereafter, a resist material was applied on the Mo film. The applied resist material was exposed to light through a photomask. Subsequently, the resist material exposed to light was developed to pattern the resist material, thereby acquiring a photoresist pattern. This series of processes of forming a photoresist pattern is referred to as a photoengraving process (photolithography process). The Mo film was patterned by selectively etching the Mo film by using the photoresist pattern (not illustrated) obtained through this first photoengraving process as an etching mask. This etching process was performed by wet etching with solution (hereinafter referred to as “PAN solution”) containing phosphoric acid, acetic acid, and nitric acid. The PAN solution preferably contains phosphoric acid of 40 to 93 wt % (weight %), nitric acid of 1 to 40 wt %, and acetic acid of 0.5 to 15 wt %, and in the example, the PAN solution containing phosphoric acid of 70 wt %, nitric acid of 7 wt %, acetic acid of 5 wt %, and water was used at a temperature of 40° C.

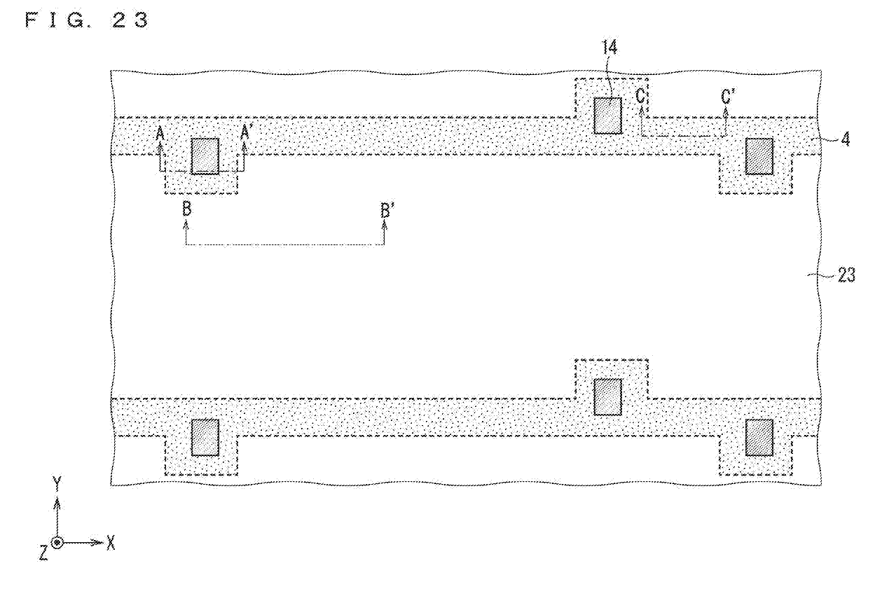

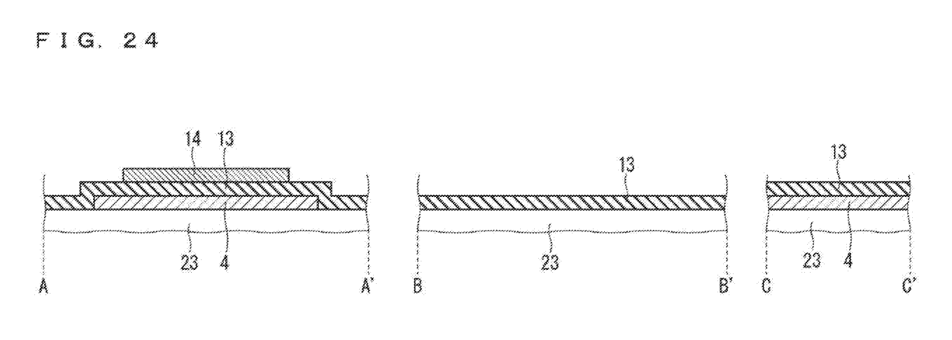

As illustrated in FIGS. 23 and 24, subsequently, the gate insulation layer 13 is formed on the glass substrate 23. Through this process, the gate lines 4 are covered by the gate insulation layer 13. The gate insulation layer 13 is, for example, a silicon nitride (SiN) layer. The SiN layer may be formed by a chemical vapor deposition (CVD) method. In the example, a SiN layer having a thickness of 300 nm was formed by using silane (SiH₄) gas, dinitrogen monoxide (N₂O) gas, and ammonia (NH₃) gas under a substrate heating condition at 150° C. to 400° C.

Subsequently, a semiconductor film as the semiconductor layers 14 is formed on the gate insulation layer 13. The gate insulation layer 13 and the semiconductor film as the semiconductor layers 14 may be continuously formed in an identical chamber. Similarly to the gate insulation layer 13, the semiconductor film may be formed by the CVD method. Specifically, first, a semiconductor layer as a channel is formed by using silane gas and hydrogen gas, and thereafter, an n-type amorphous silicon layer is formed to achieve favorable contact between the semiconductor layer and the source electrodes 5S to be formed thereon. Process gas for forming the n-type amorphous silicon layer is typically obtained by adding phosphine (PH₃) gas to silane gas and hydrogen gas. In the example, an amorphous silicon film having a thickness of 150 nm was formed by using silane gas and hydrogen gas under a substrate heating condition of 150 to 400° C., and then, an n-type amorphous silicon layer having a thickness of 50 nm was formed by using silane gas, hydrogen gas, and phosphine gas under a substrate heating condition of 150 to 400° C.

After the semiconductor film is formed, the second photoengraving process is performed. The semiconductor film is patterned by selectively etching the semiconductor film by using a photoresist pattern (not illustrated) formed through this process as an etching mask. Accordingly, the semiconductor layers 14 are obtained above the gate lines 4. Thereafter, the photoresist pattern is removed.

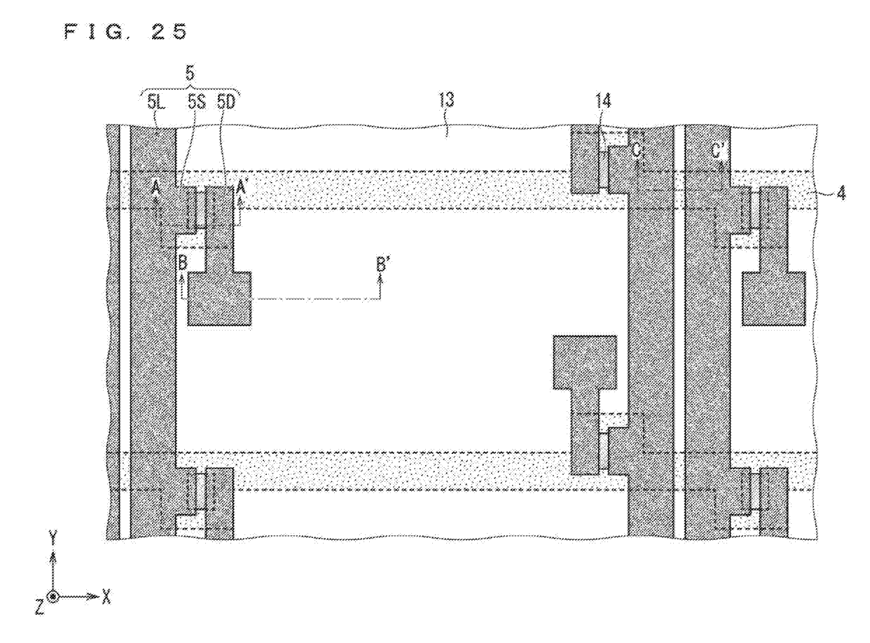

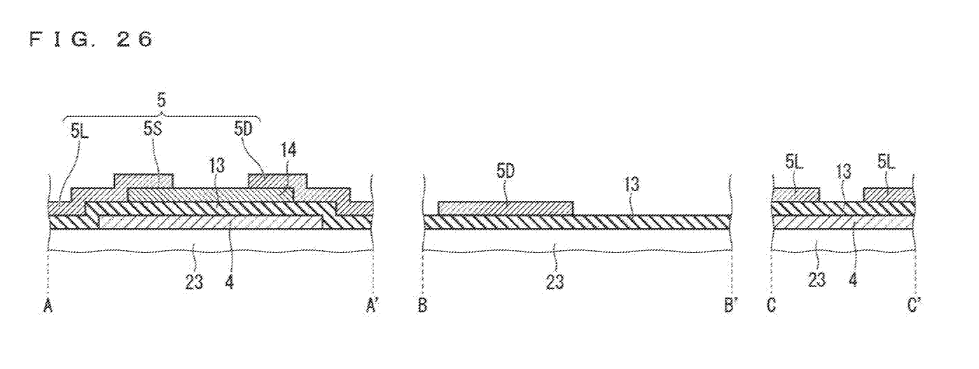

As illustrated in FIGS. 25 and 26, subsequently, the metal film 5 is formed on the glass substrate 23. The metal film 5 may be made of those exemplarily described as the material of the conductive film as the gate lines 4, thereby obtaining low electric resistance. The metal film 5 is patterned to form the source lines 5L, the source electrodes 5S, and the drain electrodes 5D. Through this process, a gap sandwiched between each source electrode 5S and the corresponding drain electrode 5D is formed on a channel part of the semiconductor layers 14. Subsequently, part of the n-type amorphous silicon layer is removed by etching in this gap so that only a semiconductor layer that functions as a channel remains. The etching of the metal film 5 may be performed by a wet etching method, and etchant may be a PAN solution. The etching performed to remove the n-type amorphous silicon layer may be performed by a dry etching method.

In the example, a Mo film having a thickness of 200 nm was deposited as the metal film 5 by a sputtering method using Ar gas. Thereafter, a photoresist pattern (not illustrated) was formed through the third photoengraving process. The Mo film was patterned by selectively etching the Mo film by using the photoresist pattern as an etching mask. A PAN solution containing phosphoric acid of 70 wt %, nitric acid of 7 wt %, acetic acid of 5 wt %, and water was used as etchant at a temperature of 25° C. The etching of an n-type amorphous silicon layer was performed by dry etching with gas (for example, SF₆) containing fluorine, oxygen gas, and argon gas. Thereafter, the photoresist pattern was removed.

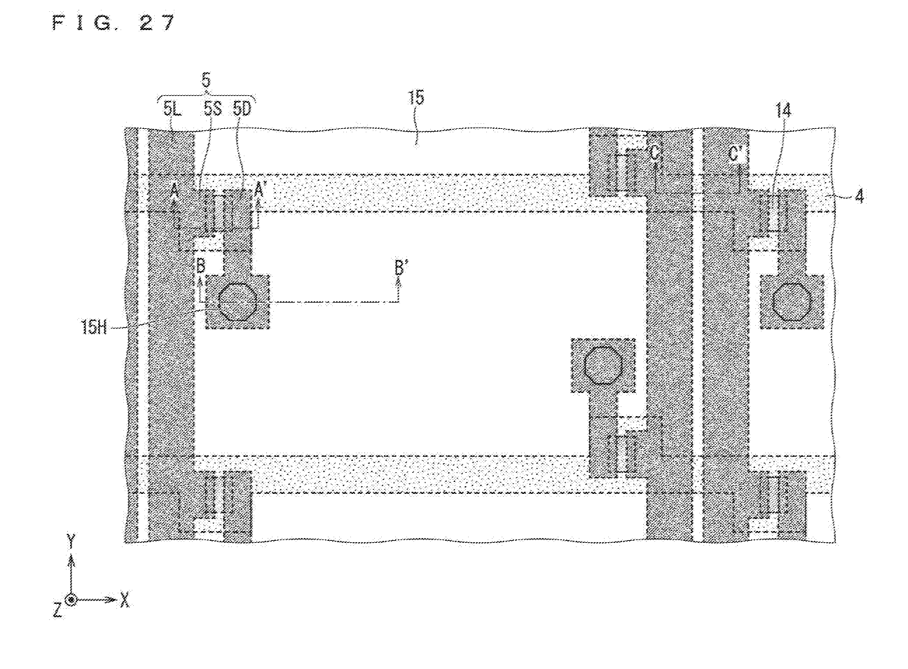

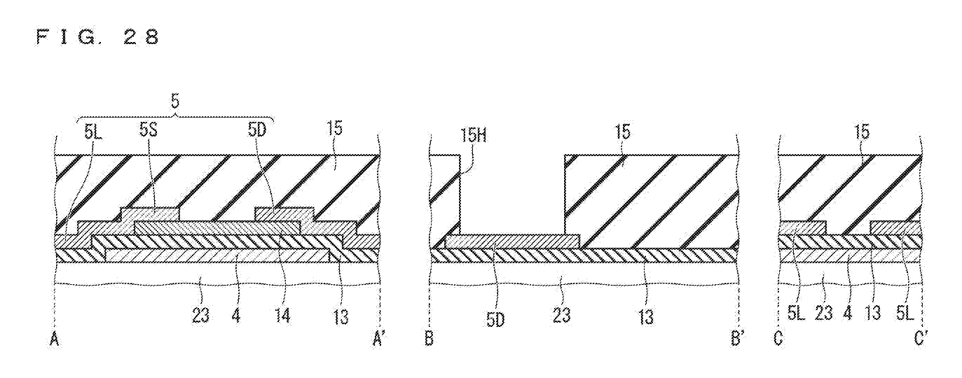

As illustrated in FIGS. 27 and 28, subsequently, the first interlayer insulation layer 15 is formed to cover the metal film 5. For example, a SiN layer having a thickness of 300 nm is formed, by the CVD method, on the glass substrate 23 being heated in a temperature range of 150 to 400° C.

Subsequently, the contact hole 15H that reaches each drain electrode 5D through the first interlayer insulation layer 15 is formed. Specifically, a photoresist pattern is formed through the fourth photoengraving process. The SiN layer is selectively etched by using the photoresist pattern as an etching mask. This etching may be performed by a dry etching method using fluorine gas. Thereafter, the photoresist pattern is removed.

The first interlayer insulation layer 15 may be formed by a method other than the CVD method. For example, an organic film or an SOG film may be formed by using a spin coat or a slit coat. When the first interlayer insulation layer 15 is made of a light-sensitive material, the first interlayer insulation layer 15 can be patterned through a photoengraving process using the material without etching and subsequent removal of a photoresist pattern. Alternatively, an organic film or an SOG film may be formed on a SiN layer after the SiN layer is formed by the CVD method, and may be patterned thereafter. In this case, the reliability of the TFT 8 and the flatness of the first interlayer insulation layer 15 can be both increased.

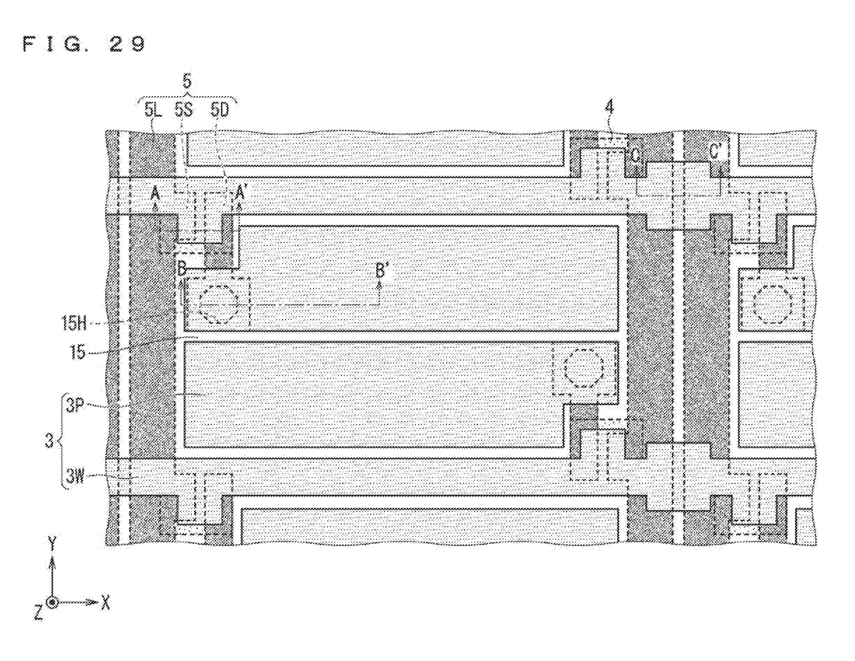

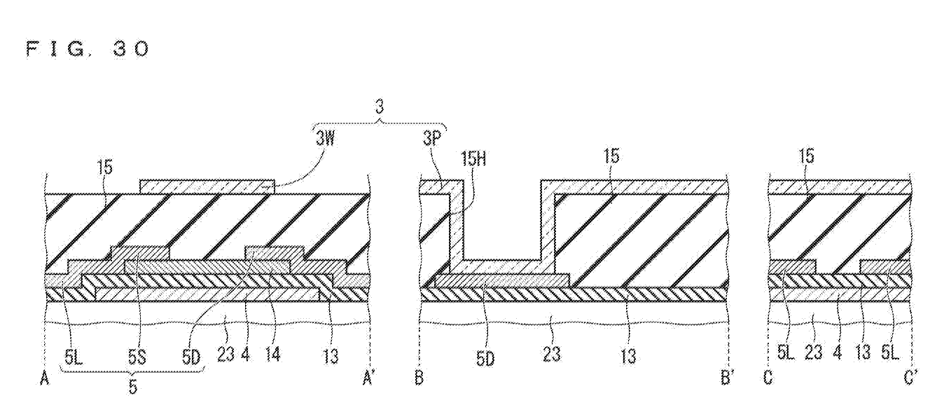

As illustrated in FIGS. 29 and 30, subsequently, the conductive film 3 is formed to cover the first interlayer insulation layer 15 and embed the contact hole 15H. The conductive film 3 is formed as a transparent conductive film. In the example, an InZnO film (IZO film), which is a conductive oxide film, was formed to have a thickness of 100 nm by a sputtering method. The InZnO film containing indium oxide (In₂O₃) and zinc oxide (ZnO) at a mixture ratio of 90:10 in weight % was used. The transparent conductive film is not limited to an indium zinc oxide (IZO) film, and may be, for example, an indium tin oxide (ITO) film.

Thereafter, a photoresist pattern (not illustrated) is formed on the conductive film 3 through the fifth photoengraving process. The conductive film 3 is patterned by selectively etching the conductive film 3 by using the photoresist pattern as an etching mask. Through this process, the common lines 3W and the pixel electrodes 3P are formed. Thereafter, the photoresist pattern is removed. This etching process may be performed by wet etching with an oxalic acid solution.

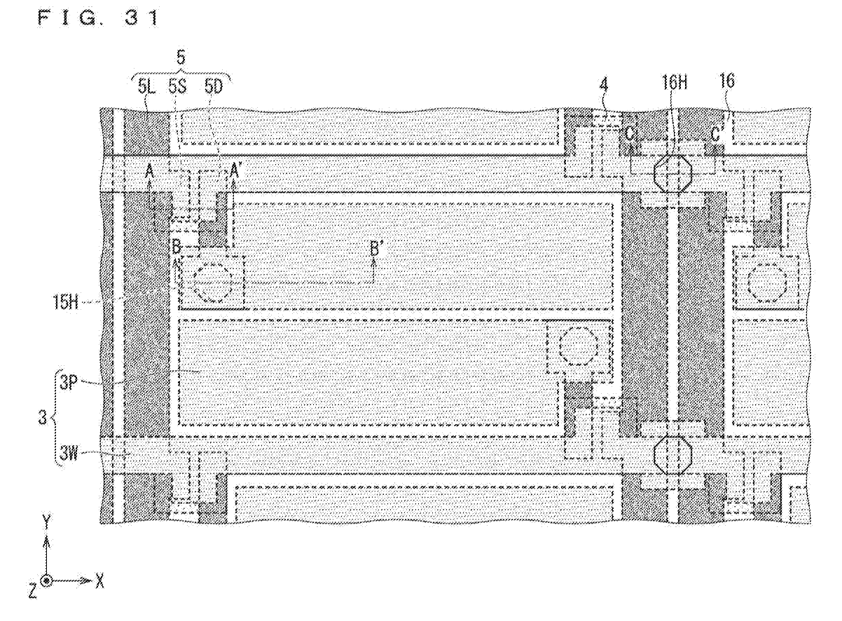

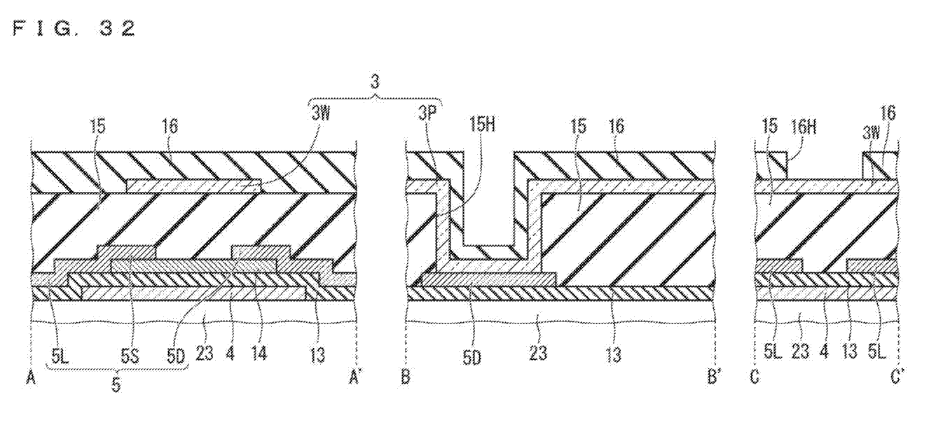

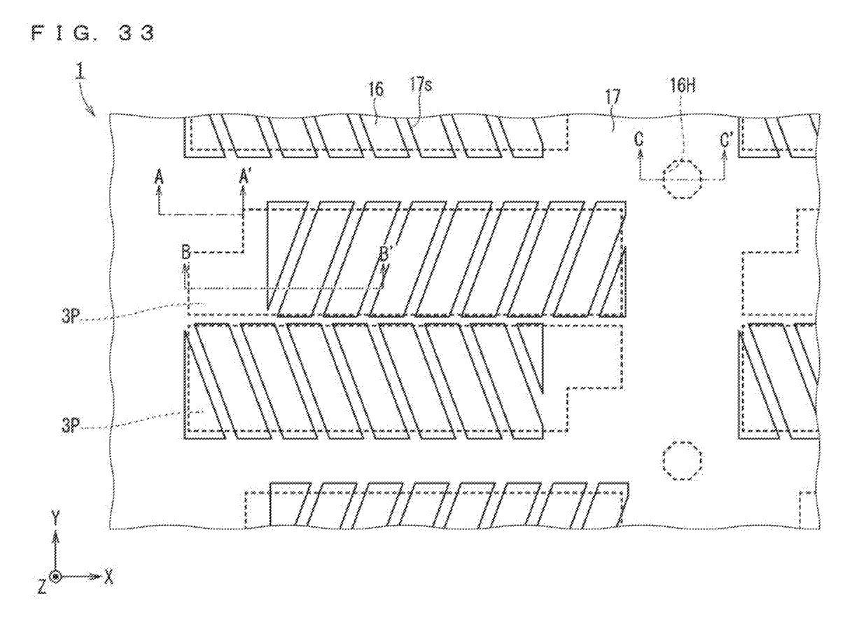

As illustrated in FIGS. 31 and 32, subsequently, the second interlayer insulation layer 16 is formed to cover the conductive film 3. For example, the CVD method was employed to form a SiN layer. In the example, a SiN layer having a thickness of 300 nm was formed by using silane (SiH₄) gas, dinitrogen monoxide (N₂O) gas, and ammonia (NH₃) gas under a substrate heating condition of 150 to 250° C. When the first interlayer insulation layer 15 is formed as an organic film, the first interlayer insulation layer 15 is yellowed through substrate heating in some cases, and thus an excessively high substrate heating temperature needs to be avoided at formation of the second interlayer insulation layer 16.

Thereafter, the contact hole 16H is formed in the second interlayer insulation layer 16. Specifically, a photoresist pattern is formed on the second interlayer insulation layer 16 through the sixth photoengraving process. The SiN layer is selectively etched by using the photoresist pattern as an etching mask. This etching may be performed by a dry etching method using fluorine gas.

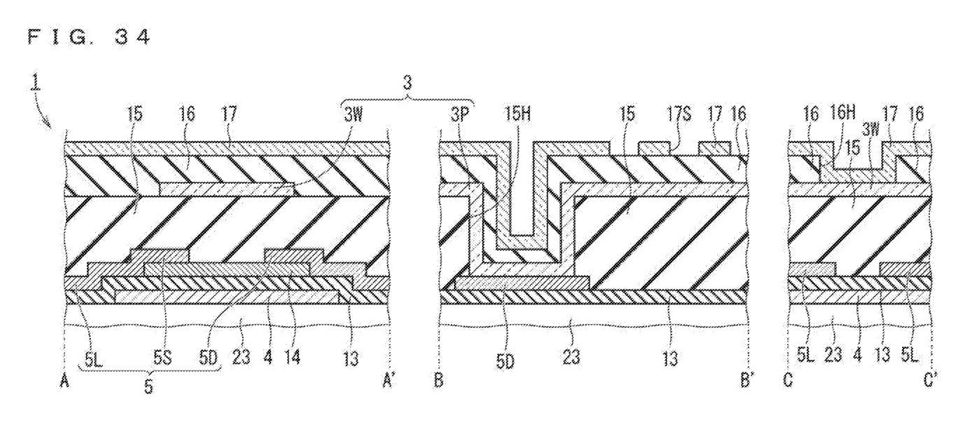

As illustrated in FIGS. 33 and 34, subsequently, the common electrode 17 is formed to cover the second interlayer insulation layer 16 and embed the contact hole 16H. The common electrode 17 is formed as a transparent conductive film. In the example, similarly to the conductive film 3, the transparent conductive film was formed as an IZO film. The transparent conductive film is not limited to an IZO film, and may be, for example, an ITO film.

Thereafter, a photoresist pattern (not illustrated) is formed on the common electrode 17 through the seventh photoengraving process. The slits 17s are formed in the common electrode 17 by selectively etching the common electrode 17 by using the photoresist pattern as an etching mask. This etching process may be performed by wet etching with an oxalic acid solution. Thereafter, the photoresist pattern is removed.

In this manner, the array substrate 1 is obtained.

(Method of Manufacturing Liquid Crystal Display Device 90)

The alignment film 18 (FIG. 9) and the spacer (not illustrated) are formed on the surface of the array substrate 1 obtained by the above-described manufacturing method. The alignment film is a film for arraying liquid crystal molecules, and contains, for example, polyimide. In addition, the counter substrate 2 is prepared. Then, the array substrate 1 and the counter substrate 2 are bonded to each other. Subsequently, the array substrate 1 and the counter substrate 2 bonded to each other are immersed into an etching solution of hydrogen fluoride (HF) or buffered hydrogen fluoride (BHF; HF+NH₄F). By etching performed through this process, the thicknesses of the glass substrate 23 and the glass substrate 24 included in the array substrate 1 and the counter substrate 2 are reduced to the range of 0.05 mm and 0.3 mm, and for example, reduced to 0.15 mm approximately. When the thicknesses are too small, cracking is likely to occur in a subsequent process (for example, a liquid crystal injection process or a polarization plate bonding process to be described later). On the other hand, when the thicknesses are too large, the glass substrate 23 and the glass substrate 24 are difficult to curve, and thus cracking is likely to occur in a curving process.

Subsequently, cutting is performed by using a glass scriber or the like to achieve fabrication into the size of one liquid crystal display device. At a position facing to a side of the array substrate 1 at which a wiring terminal connected with an external image signal output unit is disposed, the counter substrate 2 is cut inside of a place at which a connection terminal is formed. Then, liquid crystal is injected into a gap formed between the substrates through the spacer, thereby forming the liquid crystal layer 19. Thereafter, the polarization plates 22 are disposed outside of the substrates.

In this manner, the liquid crystal panel 50 is obtained.

Subsequently, the liquid crystal panel 50 and the support plate 28 are bonded to each other by using a sheet adhesive film while the liquid crystal panel 50 is pressed onto the support plate 28 (FIG. 1) by a roller or the like. The support plate 28 is obtained by forming transparent resin such as acrylic or polycarbonate into a shape curved at a predetermined curvature (curvature radius as the sum of a desired curvature radius of the display surface and the thickness of the liquid crystal panel). In the example, at an end part of the liquid crystal panel 50 in the curved direction X, slight deformation occurred to the support plate 28 due to large stress in the counter substrate 2 on the inner side, and as a result, a slight difference from the above-described curvature occurred.

The backlight 25 (FIG. 1) is stacked on the liquid crystal panel 50 curved by the support plate 28. A case (not illustrated) is placed over from the counter substrate 2 side. In addition, connection with a circuit board is achieved through a flexible substrate.

In this manner, the liquid crystal display device 90 is obtained.

### Second Preferred Embodiment

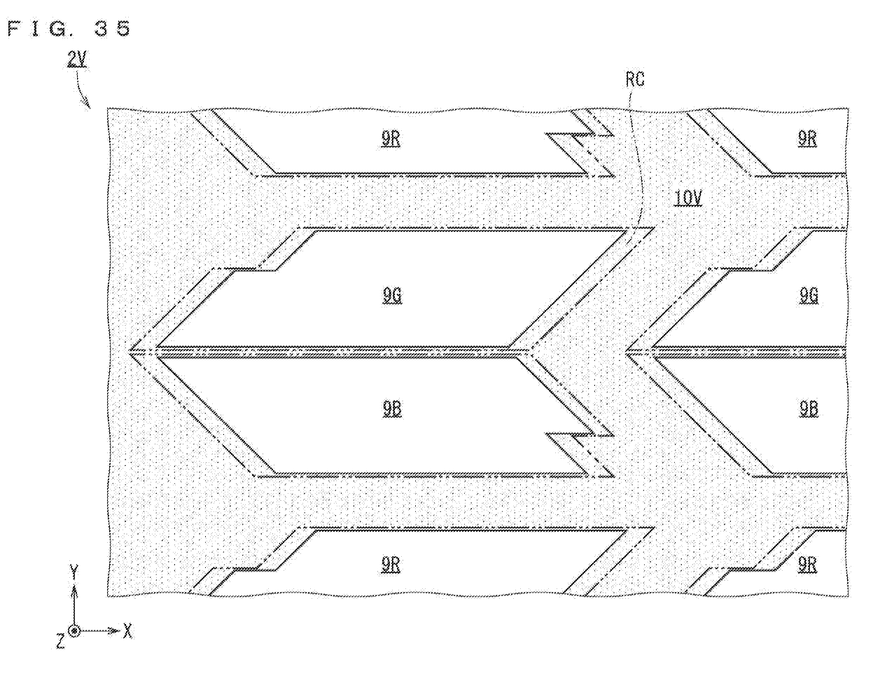

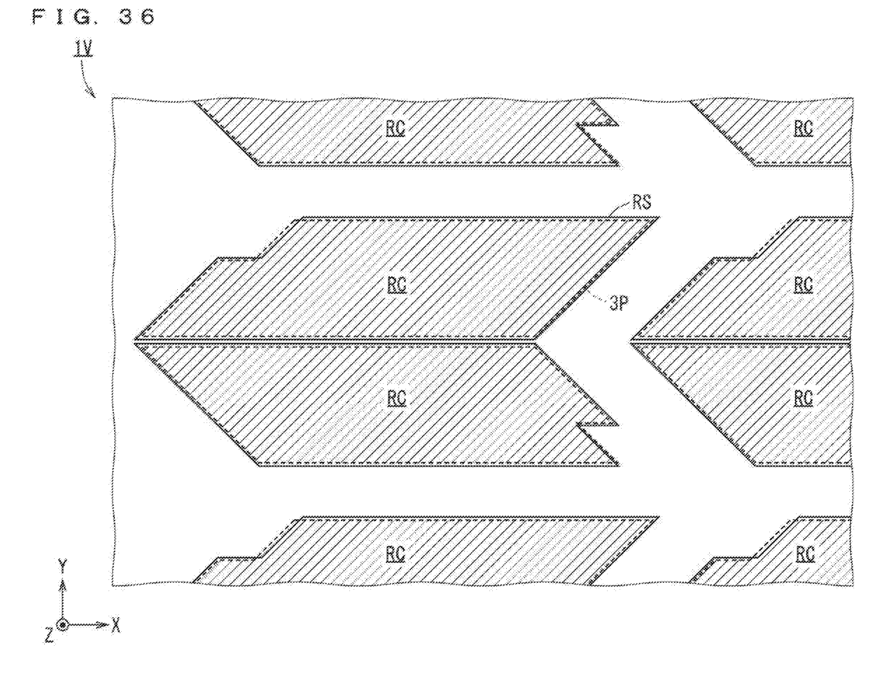

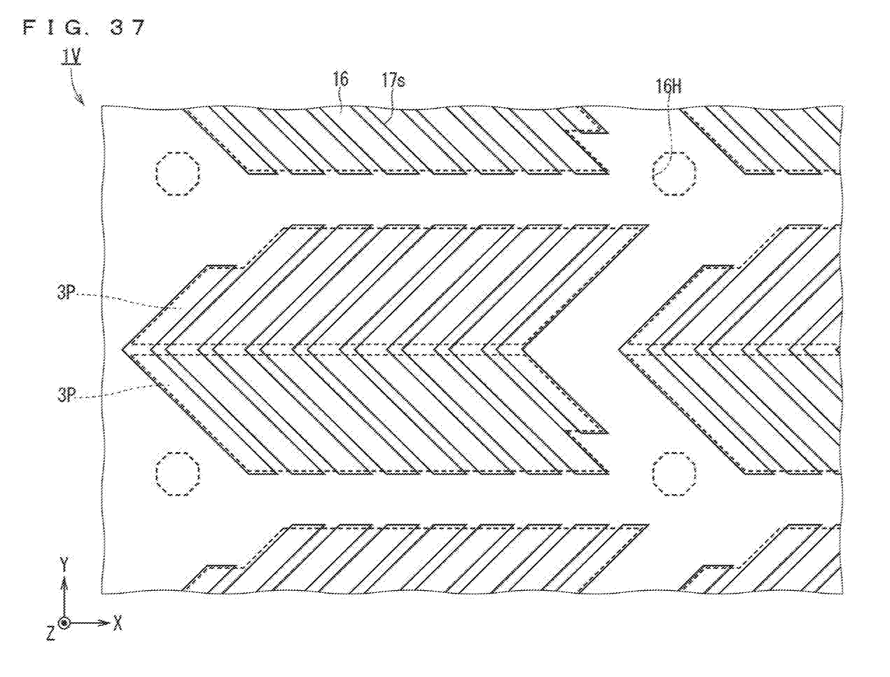

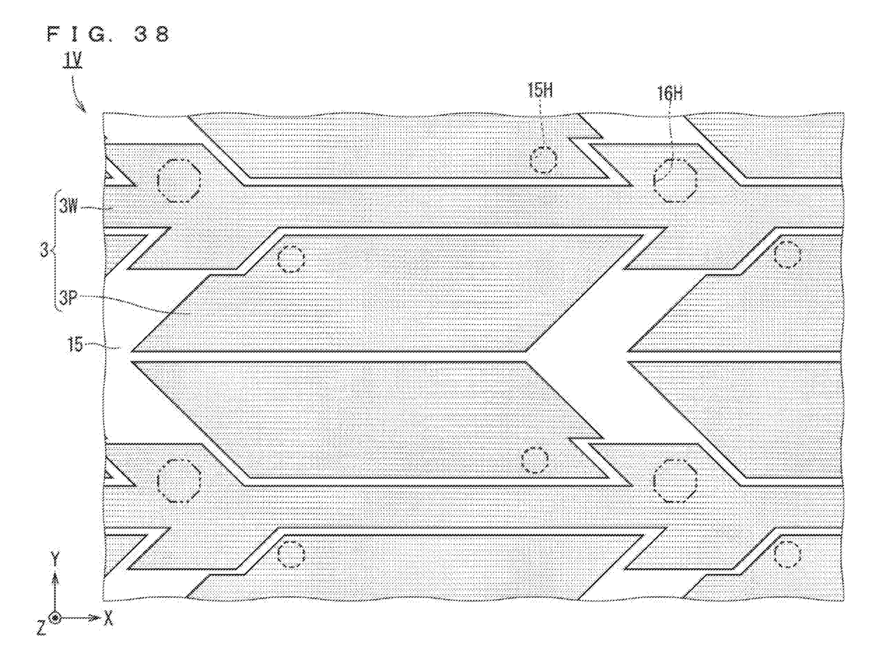

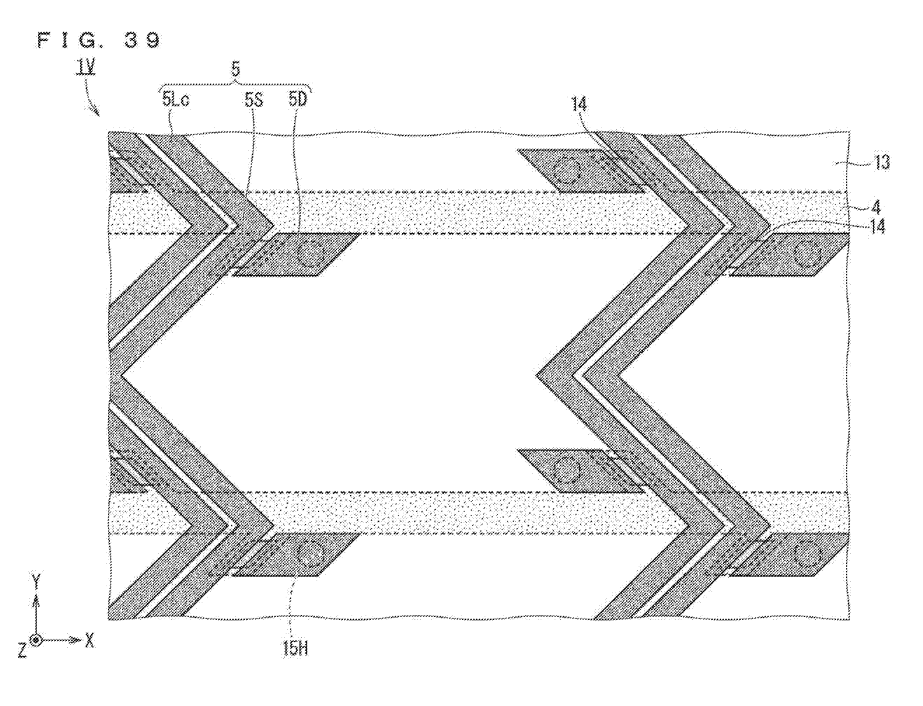

FIG. 35 is a partial plan view schematically illustrating the configuration of a counter substrate 2V according to the present preferred embodiment, which is a diagram corresponding to FIG. 4 in the first preferred embodiment. FIG. 36 is a partial plan view illustrating a situation in which the liquid crystal control region RC is formed in an array substrate 1V by the slit formation region RS of the common electrode and the pixel electrodes 3P according to the present preferred embodiment, which is a diagram corresponding to FIG. 5 in the first preferred embodiment. FIG. 37 is a partial plan view schematically illustrating the configuration of the array substrate 1V, which is a diagram corresponding to FIG. 6 in the first preferred embodiment. FIGS. 38 and 39 are partial plan views schematically illustrating the internal configuration of the array substrate 1V, which are diagrams corresponding to FIGS. 7 and 8, respectively, in the first preferred embodiment.

Although the source lines 5L (FIG. 8) according to the first preferred embodiment extend in the non-curved direction Y, source lines 5Lc (FIG. 39) according to the present preferred embodiment obliquely extend relative to the non-curved direction Y, and specifically, extend in a zigzag manner. A black matrix 10V according to the present preferred embodiment has a shape corresponding to the extending direction of the source lines 5Lc. Any other configuration is substantially same as the above-described configuration according to the first preferred embodiment, and thus any identical or corresponding component is denoted by an identical reference sign, and duplicate description thereof will be omitted. In addition, the first and second preferred embodiments are different from each other in the pattern shapes of the materials of the counter substrate and the array substrate, and accordingly, a manufacturing method according to the second preferred embodiment is substantially same as the manufacturing method according to the first preferred embodiment. Thus, description of the manufacturing method according to the present preferred embodiment will be omitted.

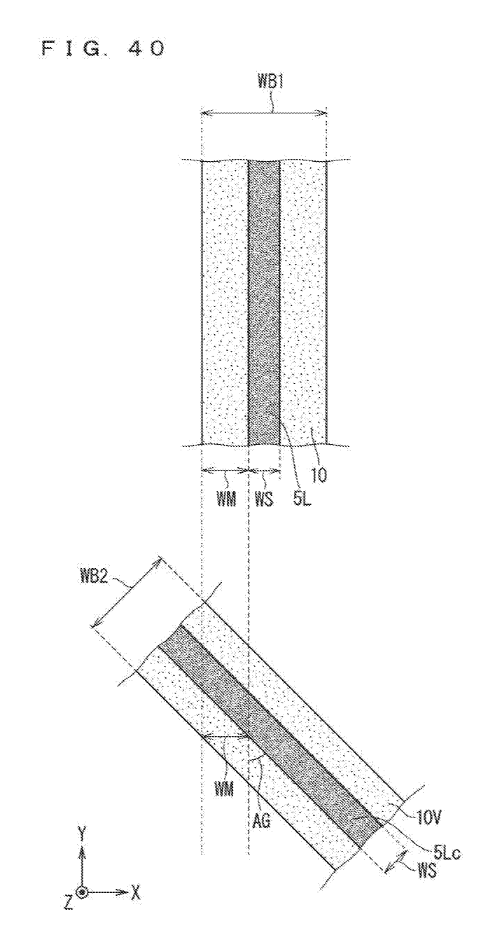

FIG. 40 is a plan view explaining width WB1 of the black matrix 10 and width WB2 of the black matrix 10V. The width WB1 of the black matrix 10 is necessary for covering, with a sufficient margin WM, the vicinity of each source line 5L extending in the non-curved direction Y. The width WB2 of the black matrix 10V is necessary for covering, with a sufficient margin WM, the vicinity of each source line 5L extending at an angle AG relative to the non-curved direction Y. As understood from FIG. 40, the width WB2 is smaller than the width WB1. Thus, when the source lines 5Lc are used in place of the source lines 5L as in the present preferred embodiment, it is possible to reduce the width of the black matrix while obtaining the margin WM sufficient for positional displacement in the curved direction X. This can be exploited to increase the aperture ratio.

The present invention allows optional combination of the preferred embodiments and appropriate deformation or omission of each preferred embodiment within the scope of the invention.

While the invention has been shown and described in detail, the forcgoing description is in all aspects illustrative and not restrictive. It is therefore understood that numerous modifications and variations can be devised without departing from the scope of the invention.

What is claimed is:

1. A liquid crystal display device including a plurality of pixel structures disposed in a matrix and including a display surface flat in a non-curved direction and curved in a curved direction orthogonal to the non-curved direction, the device comprising:
a liquid crystal layer;
a counter substrate facing to the liquid crystal layer, including a black matrix, and curved along the display surface; and
an array substrate holding the liquid crystal layer between the array substrate and the counter substrate, curved along the display surface, and provided with a plurality of first electrode lines extending in a direction orthogonal to the non-curved direction and a plurality of second electrode lines intersecting with the plurality of first electrode lines,
wherein two or more of the second electrode lines are disposed between pixel structures adjacent to each other in a direction intersecting with the non-curved direction.

2. The liquid crystal display device according to claim 1, wherein the pixel structures have a first pixel number in the non-curved direction and a second pixel number in the direction orthogonal to the non-curved direction, the number of the second electrode lines is larger than the second pixel number, and the number of the first electrode lines is smaller than the first pixel number.

3. The liquid crystal display device according to claim 1, wherein each second electrode line obliquely extends relative to the non-curved direction.

4. The liquid crystal display device according to claim 1, wherein the plurality of pixel structures each have a first dimension in the non-curved direction and a second dimension in the direction orthogonal to the non-curved direction, and the second dimension is larger than the first dimension.

5. The liquid crystal display device according to claim 1, wherein the plurality of first electrode lines are gate lines.

6. The liquid crystal display device according to claim 1, wherein the number of the first electrode lines is equal to or smaller than 1620.
